(19) United States
(12) Patent Application Publication
(10) Pub. No.: US 2014/0209471 A1
(43) Pub. Date: Jul. 31, 2014

(54) FORMING AN OXIDE LAYER ON A FLAT CONDUCTIVE SURFACE

(71) Applicants: Leonid Borisovich Rubin, Burnaby (CA); Alexander Sergeyevich Osipov, New Westminster (CA); Elena Borisovna Neburchilova, Vancouver (CA)

(72) Inventors: Leonid Borisovich Rubin, Burnaby (CA); Alexander Sergeyevich Osipov, New Westminster (CA); Elena Borisovna Neburchilova, Vancouver (CA)

(73) Assignee: CLEAR METALS, INC., North Vancouver, BC (CA)

(21) Appl. No.: 14/343,824

(22) PCT Filed: Sep. 8, 2011
(86) PCT No.: PCT/CA2011/001013

§ 371 Date: Mar. 7, 2014

(51) Int. Cl. H01L 31/0216; C25D 7/12

(52) U.S. Cl. CPC H01L 31/02168; C25D 7/12
USPC 205/91; 204/242; 204/273; 204/274; 204/278.5; 205/124

(57) ABSTRACT

A method and apparatus for electrochemically forming an oxide layer on a flat conductive surface which involves positioning a working electrode bearing the flat conductive surface in opposed parallel spaced apart relation to a flat conductive surface of a counter electrode such that the flat conductive surface of the working electrode and the flat conductive surface of the counter electrode are generally opposed, horizontally oriented, and define a space therebetween. A volume of organic electrolyte solution containing chemicals for forming the oxide layer on the flat conductive surface of the working electrode is arranged to flood the flat conductive surface of the counter electrode surface and to occupy the space defined between the flat conductive surface of the working electrode and the flat conductive surface of the counter electrode such that at least the flat conductive surface of the counter electrode is in contact with the organic electrolyte solution and substantially only the flat conductive surface of the working electrode is in contact with the organic electrolyte solution. An electric current flows between substantially only the flat conductive surface of the counter electrode and substantially only the flat conductive surface of the working electrode, in the organic electrolyte solution, for a period of time and at a magnitude sufficient to cause the chemicals to form the oxide layer on the flat conductive surface of the working electrode.

### BACKGROUND OF THE INVENTION

1. Field of Invention

The present invention generally relates to forming an oxide layer on flat conductive surfaces such as surfaces of semiconductor devices and photovoltaic (PV) cells.

2. Description of Related Art

Photovoltaic (PV) cells, and more particularly, crystalline silicon photovoltaic cells typically have a front side surface operable to receive light and a back side surface opposite the front side surface. The front side surface is part of an emitter of the PV cell and has a plurality of electrical contacts formed therein and the back side surface has at least one electrical contact. The electrical contacts on the front and back side surfaces are used to connect the PV cell to an external electrical circuit.

To improve PV cell efficiency by decreasing light reflection, the front side surface may be treated by wet chemical texturing and deposition of an antireflective coating. The antireflective coating typically comprises optically transparent materials of about 80-100 nm in thickness having a refractive index of about 1.8-2.3. Use of an antireflective coating and texturing can decrease initial light reflection from 38% to 8-12% on multi-crystalline PV cells and to 5-7% on mono-crystalline PV cells. A corresponding gain in the photovoltaic cell efficiency results.

For crystalline silicon solar cells the most common type of antireflective coating is SiN₄ deposited by means of Atmospheric Pressure Chemical Vapor Deposition (APCVD) or Plasma Enhanced Chemical Vapor Deposition (PECVD). Although practically all photovoltaic cell manufacturing companies use this type of antireflective coating, these deposition techniques require high temperatures of up to 700° C., have high energy consumption and require expensive manufacturing equipment.

SiN₄ antireflective coatings cannot be used for the production of amorphous silicon photovoltaic cells and some types of hetero-junction photovoltaic cells because these types of cells cannot withstand processing temperatures above 300° C. These types of photovoltaic cells use other types of antireflective coatings, such as conductive metal oxides including, for example, Zinc Oxide doped with Aluminum Al:Zn_{y}Oₓ, Indium Oxide doped with Fluorine F:In_{y}Oₓ, or Indium Oxide doped with Tin:InₓSn_{y}O_{z} (also known as ITO). Transparent conductive oxides have found widespread application in thin film photovoltaic cells and modules because they decrease light reflection, and assist in establishing low resistance electrical connections between current collecting metallization patterns and front or back side surfaces of PV cells.

Industrial deposition of conductive metal oxide antireflective coatings on temperature sensitive photovoltaic cells is normally performed using magnetron spattering, evaporation, or chemical vapor deposition techniques. Although these techniques do not require high temperatures, they use expensive equipment and high vacuum processes, and only provide low production capacity and result in the waste of expensive materials.

By using SiN₄ as an antireflective coating, photovoltaic cell efficiency is increased as a result of lower light reflection and because of the built-in positive electric charge of the SiN₄ layer. This built-in charge reflects negative electric charges from the front surfaces of p-type crystalline photovoltaic cells which improves passivation due to decreased charge recombination. This improved passivation results in photovoltaic cell efficiency gain.

Passivation quality similar to that of SiN₄ may be achieved if an Al₂O₃ layer about 20-200 nm in thickness having a built-in negative charge is deposited on the rear side of a p-type crystalline photovoltaic cell. This built-in negative charge reflects negative charges from the rear surface of the solar cell that are generated when the PV cell is under illumination. Aluminum oxide layers can be deposited by Atomic Layer Deposition (ALD) technologies as described by B. Hoex, J. Schmidt, P. Pohl, M. C. M. van de Sanden, and W. M. M. Kessels, in an article entitled “Silicon Surface Passivation by Atomic Layer Deposited Al₂O₃ JOURNAL OF APPLIED PHYSICS 104, p. 044903-1-044903-12, 2008; and in an article by G. Dingemans, W. Beyer, M. C. M. van de Sanden, and W. M. M. Kessels, entitled “Hydrogen Induced Passivation of Si Interfaces by Al₂O₃ Films and SiO₂/Al₂O₃Stacks”, APPLIED PHYSICS LETTERS 97, 152106_{—}2010 and by radio frequency magnetron sputtering as described by T. T. A. Li and A. Cuevas, in an article entitled “Role of Hydrogen in the Surface Passivation of Crystalline Silicon by Sputtered Aluminum Oxide; PROGRESS IN PHOTOVOLTAICS: RESEARCH AND APPLICATIONS, 2011; 19:320-325. Unfortunately these technologies are quite expensive and do not provide sufficient production capacity.

The passivation effect of an Al₂O₃ layer may be used to improve crystalline silicon photovoltaic cell efficiency if cost-efficient techniques and equipment can be developed and commissioned into mass production.

An efficient passivation of the crystalline silicon solar cell may be achieved by forming a silicon oxide (SiO₂) passivation layer to have a thickness of about 10 nm to 20 nm on the front and/or rear surfaces of the solar cell. Efficient passivation occurs due to the strong reduction of the Si interface defect density. The SiO₂ passivation layer may be formed by thermal methods at very high temperatures (˜1050° C.) or through the use of wet oxidation processes with H₂O at ˜800° C. in wet atmosphere environment such as described by G. Dingemans, M. C. M. van de Sanden, and W. M. M. Kessels, in an article entitled “Excellent Si Surface Passivation by Low Temperature SiO₂ using an Ultrathin Al₂O₃ Capping Film”, Phys. Status Solidi RRL 5, No. 1, 22-24 (2011). Unfortunately these processes are expensive, consume a large amount of energy and do not facilitate great accuracy in the production of the SiO₂ layer to a desired thickness and uniformity. Many efforts have been undertaken to avoid the long processing times and the very high temperatures (˜1050° C.) required for thermal SiO₂ formation, to prevent deterioration of the Si bulk quality. However, to date, the best surface passivation performance can be obtained by low temperature alternatives such as nitric acid oxidation (NAOS) and chemical vapour deposition (CVD) which produce considerably poorer quality SiO₂ layers and lower quality passivation than can be obtained with thermally-grown SiO₂.

Alternative methods involve the use of electrochemical plating techniques to form metal oxide layers such as aluminum oxide, zinc oxide or indium oxide layers on semiconductor substrates.

U.S. Pat. No. 6,346,184 B1 entitled “Method of Producing Zinc Oxide Thin Film, Method of Producing Photovoltaic Device and Method of Producing Semiconductor Device” to Masafumi Sano, Souraku-gun, Yuichi Sonoda describes a method of producing a zinc oxide thin film in which a current is passed between a conductive substrate immersed in an aqueous solution containing at least zinc ions and carboxylic acid ions, and an electrode immersed in the aqueous solution to form a zinc oxide thin film on the conductive substrate. This method stabilizes formation of the zinc oxide thin film and improves adhesion between the thin film and the substrate. The zinc oxide film is deposited on a cathode comprising an optically transparent or non-transparent substrate coated with transparent conductive material such as indium oxide (In₂O₃), indium tin oxide (In₂O₃+SnO₂), zinc oxide (ZnO), or tin oxide (SnO₂) deposited by spattering, vacuum deposition or chemical vapor deposition methods. The optically non-transparent conductive substrate on the cathode may be a flexible stainless steel film of 0.15 mm thickness coated with a silver and or conductive zinc oxide layer. The back side of the stainless steel film is covered with an electrically insulating film to prevent electrochemical deposition of the zinc oxide layer thereon. Metallic foil could be used as a non-transparent conductive substrate. The patent discloses that a 4-N purity zinc plate was used as the anode. The aqueous electrolyte solution described is an aqueous ammonia solution of zinc hydroxide, zinc oxalate or zinc oxide in concentrations of 0.001 to 3.0 mol/L and hydrogen ion exponent (pH) between a pH of 8 and a pH of 12.5.

U.S. Pat. No. 6,110,347 entitled “Method for the Formation of an Indium Oxide Film by Electrodeposition Process or Electroless Deposition Process, a Substrate Provided with the Indium Oxide for a Semiconductor Element and a Semiconductor Element Provided with the Substrate” to Kozo Arao, Nara; Katsumi Nakagwa; and Yukiko Iwasaki describes a method of producing an indium oxide film on an electrically conductive substrate by immersing the substrate and a counter electrode in an aqueous solution containing at least nitrate and indium ions and causing an electric current to flow between the substrate and the counter electrode, thereby causing an indium oxide film to form on the substrate. A film-forming method for the formation of an indium oxide on a substrate by an electroless deposition process, using the aqueous solution, and a substrate for a semiconductor element and a photovoltaic element produced using the film-forming method are further provided. In the process described, the negative cathode electrode can be made from any conductive metal or alloy. For example, the cathode may be a 0.12 mm thick stainless steel plate having a rear surface covered with insulating tape for protection against deposition of indium oxide thereon. The positive anode electrode may be made from a 0.2 mm thick platinum plate of 4-N purity. The electrolyte may be an aqueous solution containing indium nitrate with sucrose or dextrin. Notably, the electrolyte must always be stirred by means of a magnetic agitator.

U.S. Pat. No. 6,133,061 entitled “Method for Forming Thin Zinc Oxide Film, and Method for Producing Semiconductor Element Substrate and Photovoltaic Element Using Zinc Oxide Thin Film” to Yuichi Sonoda describes a method for forming a thin film of zinc oxide on a conductive substrate by electrode position from an aqueous solution, while preventing film deposition on the back surface of the substrate. More specifically, a film deposition-preventing electrode for preventing film deposition on the back surface of the substrate is provided in an aqueous solution containing nitrate ions, and a current is supplied such that the counter electrode is at a higher potential than the substrate which is at a higher potential than the film deposition-preventing electrode. This method can be applied to a process for preparing a solar cell. Unfortunately, the method requires the use of a third counter electrode for protecting the back side of the conductive substrate from unwanted electrochemical treatment.

There are a number of disadvantages of the methods disclosed in U.S. Pat. Nos. 6,346,184, 6,110,347, and 6,133,061. Although the methods allow for the deposition zinc oxide films on metallic or semiconductor conductive substrates, they require electric insulation of the rear sides of the substrates to prevent zinc oxide deposition thereon. Further, the above methods require to continuous stirring of the electrolyte solution during deposition. In addition, the use of aqueous electrolyte solutions requires very careful control of the pH in a narrow range to prevent precipitation of zinc/indium hydroxide at higher pH values, and to avoid dissolution of zinc/indium hydroxide/oxide from the substrate at lower pH values. Further the methods disclosed in the above US patents may not provide reliable techniques for in-situ control of film thickness.

Yet another disadvantage of the above patents is the use of aqueous electrolyte solutions. It is known that deposition of ZnO films from aqueous zinc salt solutions will be accompanied with the formation of hydroxide which degrades the quality of ZnO films [S. Peulon, D. Lincot, Mechanistic Study of Cathodic Electrodeposition of Zinc Oxide and Zinc Hydroxychloride Films from Oxygenated Aqueous Zinc Chloride Solutions J. Electrochem. Soc., 45 (1998), 864-874]. High deposition temperatures (60-85° C.) need to be used in aqueous baths in order to shift an equilibrium balance of a hydroxide/oxide reaction to the preferred formation of oxide [D. Chu, Y. Masuda, T. Ohji, and K. Kato, Shape-Controlled Growth of In(OH)₃/In₂O₃ Nanostructures by Electrodeposition, Langmuir 2010, 26(18), 14814-14820]. Even high temperature (65-85° C.) electrodeposition of indium oxide/hydroxide from aqueous solutions of indium salts does not prevent a preferential growth of indium hydroxide nanostructures. Further, drying at 80° C. for 10 hours and annealing at 300° C. for 30 min is required in order to obtain indium oxide by dehydration of indium hydroxide.

### SUMMARY OF THE INVENTION

In accordance with one aspect of the present invention, there is provided a method of electrochemically forming an oxide layer on a flat conductive surface. The method involves positioning a working electrode bearing the flat conductive surface in opposed parallel spaced apart relation to a flat conductive surface of a counter electrode such that the flat conductive surface of the working electrode and the flat conductive surface of the counter electrode are generally opposed and horizontally oriented and define a space therebetween. The method further involves causing a volume of organic electrolyte solution containing chemicals for forming the oxide layer on the flat conductive surface of the working electrode to flood the flat conductive surface of the counter electrode surface and occupy the space defined between the flat conductive surface of the working electrode and the flat conductive surface of the counter electrode such that at least the flat conductive surface of the counter electrode is in contact with the organic electrolyte solution and substantially only the flat conductive surface of the working electrode is in contact with the organic electrolyte solution. The method further involves causing an electric current to flow between substantially only the flat conductive surface of the counter electrode and substantially only the flat conductive surface of the working electrode, in the organic electrolyte solution, for a period of time and at a magnitude sufficient to cause the chemicals to form the oxide layer on the flat conductive surface of the working electrode.

The method may involve causing the volume of organic electrolyte solution to occupy the space defined between the flat counter electrode surface and the flat conductive surface of the working electrode may involve holding the working electrode such that substantially only the flat conductive surface of the working electrode is in contact with the organic electrolyte solution but the entire working electrode is not immersed in the organic electrolyte solution.

Holding may include protecting a substantial portion of a side of the working electrode, opposite the flat conductive surface of the working electrode, from contact with the electrolyte solution.

Protecting may involve holding a rear side of the working electrode against a holding surface bearing a seal operably configured to contact the rear side of the working electrode adjacent an outer perimeter edge of the rear side of the working electrode.

Holding the working electrode against the holding surface may include causing a negative pressure to occur adjacent the rear side of the working electrode so that ambient pressure presses the rear side of the working electrode against the seal.

Causing the negative pressure may involve providing a vacuum adjacent the seal.

The flat conductive surface of the working electrode and the flat conductive surface of the counter electrode may be spaced apart by a distance that facilitates adhesion of the organic electrolyte solution to the flat conductive surface of the working electrode and the flat conductive surface of the counter electrode due to capillary force of the organic electrolyte solution.

Positioning the working electrode may involve positioning the working electrode such that the flat conductive surface of the working electrode is between about 0.1% to about 20% of a length of the working electrode, from the flat conductive surface of the counter electrode.

Positioning the working electrode in relation to the flat conductive surface of the counter electrode may involve holding the counter electrode in a generally horizontal orientation in a container operably configured to hold the organic electrolyte solution and holding the working electrode in the container, spaced apart from the counter electrode, such that the space is defined between the flat conductive surface of the working electrode and the flat conductive surface of the counter electrode.

Causing the volume of organic electrolyte solution to flood the flat conductive surface of the counter electrode may involve admitting a pre-defined volume of the organic electrolyte solution into the container.

Admitting the pre-defined volume of the organic electrolyte solution may involve passing the pre-defined volume through an opening in the counter electrode, the opening may be in communication with the space between the flat conductive surface of the working electrode and the flat conductive surface of the counter electrode.

Passing the pre-defined volume through an opening may involve pumping the predefined volume of the organic electrolyte solution from a reservoir through the opening.

The method may involve draining the organic electrolyte solution after the oxide layer is formed to a desired thickness on the flat conductive surface of the working electrode.

The chemicals may involve a source of oxygen sufficient to permit the oxide layer to be formed to a desired thickness.

The source of oxygen may involve dissolved oxygen or at least one oxygen precursor.

The source of oxygen may involve at least one oxygen precursor and the at least one oxygen precursor may involve at least one of dissolved nitrate, nitrite, hydrogen peroxide and traces of water.

### Anode Reaction

The working electrode may be formed of a material and the oxide layer may be an oxide of the material and causing the electric current to flow may involve causing the electric current to flow in a direction such that the working electrode acts as an anode.

The method may involve agitating the organic electrolyte solution while the electric current is flowing.

Agitating may involve causing a flow of the organic electrolyte solution to pass through the space defined between the flat conductive surface of the working electrode and the flat conductive surface of the counter electrode.

The organic electrolyte solution may be protic and the chemicals may include at least one of methanol, ethanol, isopropanol, ethylene glycol, and tetrahydrofurfuryl alcohol.

The organic electrolyte solution may be aprotic and the chemicals may include at least one of N-methylacetamide and acetonitrile.

The organic electrolyte solution and the working electrode and the counter electrode may be generally maintained at a constant temperature of between about 15 degrees Celsius to about 90 degrees Celsius.

Causing the electric current to flow may involve maintaining the electric current at a level at least sufficient to maintain oxide formation on the working electrode as oxide formation occurs and presents resistance to the electric current.

The method may involve terminating the flow of electric current when the flow of electric current meets a criterion.

The criterion may include a condition that the oxide layer has a pre-defined thickness,

The current may have a current density of between about 1 mA/cm² to about 100 mA/cm².

### Cathode Reaction

The oxide layer may be a metal oxide layer and causing the electric current to flow may involve causing the electric current to flow in a direction such that the working electrode acts as a cathode and the organic electrolyte solution may include at least one ionic source of metal.

The method may involve determining the pre-defined volume based on the desired thickness of the metal oxide desired to be plated onto the flat conductive surface of the cathode and based on a concentration of the ionic source of metal and a volume of the organic electrolyte solution.

The oxide layer may include a metal oxide film of aluminum oxide and the ionic source of metal may include at least one dissolved aluminum salt or at least one aluminate or a combination of the at least one dissolved aluminum salt or at least one aluminate.

The oxide layer may include a metal oxide film of indium oxide and the ionic source of metal may include at least one dissolved indium salt.

The oxide layer may include a metal oxide film of zinc oxide and the ionic source of metal may involve at least one dissolved zinc salt or at least one zincate or a combination of the at least one dissolved zinc salt or at least one zincate.

The oxide layer may include a metal oxide film of aluminum-doped zinc oxide and the ionic source of metal may involve at least one dissolved zinc salt and at least one dissolved aluminum salt.

The oxide layer may include a metal oxide film of indium-doped zinc oxide and the ionic source of metal may involve at least one dissolved zinc salt and at least one dissolved indium salt.

The oxide layer may include a metal oxide film comprising chlorine-doped zinc oxide and the ionic source of metal may involve at least one dissolved zinc salt and the organic electrolyte solution may involve at least one dissolved chloride.

The oxide layer may include a metal oxide film of tin-doped indium oxide and the ionic source of metal may involve at least one dissolved indium salt and at least one dissolved tin salt.

The method may involve maintaining the organic electrolyte solution still while the electric current is flowing.

The organic electrolyte solution may be protic and the chemicals may include at least one of methanol, ethanol, propanol, isopropanol, ethylene glycol, and glycerol.

The organic electrolyte solution may be aprotic and the chemicals may include at least one of dimethylsulfoxide (DMSO) and propylene carbonate.

The organic electrolyte solution and the working electrode and the counter electrode may be maintained at a temperature between about 15 degrees Celsius to about 90 degrees Celsius.

The method may involve terminating the flow of electric current when a pre-defined number of coulombs has passed through the organic electrolyte solution.

The pre-defined number of coulombs may be sufficient to cause substantially all of the ionic source of metal in the electrolyte solution to be depleted from the organic electrolyte solution and oxidized on the flat conductive surface of the working electrode to facilitate producing the oxide layer to a desired thickness.

Maintaining the electric current at a level may involve maintaining the electric current at a level that produces a current density of between about 0.1 mA/cm² to about 100 mA/cm² in the organic electrolyte solution.

The electric current may be maintained at a level that produces an electric current concentration between about 1 mA/cm³ to about 1000 mA/cm³ in the organic electrolyte solution.

The method may involve draining the organic electrolyte solution substantially depleted of the metal ions after the flat conductive surface of the cathode has been plated by the metal oxide to the desired thickness.

Anodic Reaction Applied to Semiconductor wafers

The working electrode may be a semiconductor wafer, the flat conductive surface may be on a front side or a back side of the semiconductor wafer and the oxide layer may be a semiconductor oxide layer. The semiconductor oxide may layer may be formed directly on the flat conductive surface of the working electrode or may be formed through a metal oxide layer already formed thereon.

The semiconductor wafer may include an n-type crystalline semiconductor wafer or a p-type crystalline semiconductor wafer.

The flat conductive surface may be on an n-type portion or a p-type portion of the crystalline semiconductor wafer or the flat conductive surface may be on a metal oxide layer on an n-type portion or a p-type portion of the crystalline semiconductor wafer.

The method may further include exposing the flat conductive surface of the working electrode to light for at least a portion of a time during which the electric current may be flowing.

Exposing the flat conductive surface of the working electrode to light may involve admitting light into the space between the flat conductive surface of the working electrode and the flat conductive surface of the counter electrode.

Admitting light into the space may involve admitting light through openings in the counter electrode or admitting light through at least a portion of at least one peripheral edge of the space.

### Cathodic Reaction Applied to Semiconductor Wafers

The working electrode may be a semiconductor wafer, the flat conductive surface of the working electrode may be on a front side or a back side of the semiconductor wafer and oxide may be a metal oxide. The metal oxide may be formed directly on the flat conductive surface or may be formed on a semiconductor oxide layer already on the flat conductive surface.

The flat conductive surface of the working electrode semiconductor wafer may involve an n-type portion or a p-type portion of a crystalline silicon photovoltaic cell.

The method may further include exposing the flat conductive surface of the working electrode to light for at least a portion of a time during which the electric current is flowing.

Exposing the flat conductive surface of the working electrode to light may involve admitting light into the space between the flat conductive surface of the working electrode and the flat conductive surface of the counter electrode.

Admitting light in the space may involve admitting light through openings in the counter electrode or admitting light through at least a portion of at least one peripheral edge of the space.

In accordance with another aspect of the present invention, there is provided an apparatus for electrochemically forming an oxide layer on a flat conductive surface. The apparatus includes a container operably configured to hold a volume of organic electrolyte solution containing chemicals for forming the oxide layer, and a counter electrode having a flat conductive surface in a generally horizontal orientation in the container such that the organic electrolyte solution floods the flat conductive surface of the counter electrode. The apparatus further includes a working electrode holder for holding a working electrode bearing the flat conductive surface onto which the oxide layer is to be formed in a generally horizontal orientation opposite, parallel and spaced apart from the counter electrode such that a space is defined between the flat conductive surface of the counter electrode and the flat conductive surface of the working electrode. At least some of the organic electrolyte solution can occupy the space and contact the flat conductive surface of the counter electrode and the flat conductive surface of the working electrode. The apparatus further includes a direct current source operably configured to be connected to the counter electrode and the working electrode to cause an electric current to flow between the counter electrode and the working electrode to cause the working electrode to act as an anode or as a cathode in the at least some of the organic electrolyte solution.

The working electrode holder may be operably configured to hold the working electrode such that substantially only the flat conductive surface of the working electrode is in contact with the organic electrolyte solution but the entire working electrode is not immersed in the organic electrolyte solution.

The working electrode holder may include a protector operably configured to protect a substantial portion of a side of the working electrode from contact with the electrolyte solution.

The protector may include a holding surface bearing a seal operably configured to contact a rear side of the working electrode adjacent an outer perimeter edge of the rear side of the working electrode.

The working electrode holder may include provisions for causing a negative pressure to occur adjacent the rear side of the working electrode so that ambient pressure presses the rear side of the working electrode against the seal with sufficient force to prevent leakage of the electrolyte solution past the seal.

The provisions for causing a negative pressure may include a vacuum opening adjacent the seal.

The working electrode holder may be operably configured to space the flat conductive surface of the working electrode from the flat conductive surface of the counter electrode by a distance that facilitates adhesion of the organic electrolyte solution to the flat conductive surface of the working electrode and the flat conductive surface of the counter electrode due to capillary force of the organic electrolyte solution.

The working electrode holder may be operably configured to position the working electrode such that the flat conductive surface of the working electrode is between about 0.1% to about 20% of a length of the working electrode, from the flat conductive surface of the counter electrode.

The counter electrode may include a graphite plate, gas carbon plate, or graphite fabric, or a platinum plate.

The apparatus may include provisions for admitting a pre-defined volume of the organic electrolyte solution into the container.

The provisions for admitting the pre-defined volume of the organic electrolyte solution may include an opening in the counter electrode, through which the pre-defined volume is passed into the container.

The provisions for admitting the pre-defined volume of the organic electrolyte solution may include a pump operably configured to pump the predefined volume of the organic electrolyte solution from a reservoir and through the opening.

The apparatus may include a drain operably configured to drain the organic electrolyte after the oxide layer is formed to a desired thickness on the flat conductive surface of the working electrode.

The chemicals may include a source of oxygen sufficient to permit the oxide layer to be formed to a desired thickness.

The source of oxygen may include dissolved oxygen or at least one oxygen precursor.

The source of oxygen may include at least one oxygen precursor and the at least one oxygen precursor may include at least one of dissolved nitrate, nitrite, hydrogen peroxide and traces of water.

### Anode Reaction

The direct current source may be operably configured to cause the electric current to flow in a direction in which the working electrode acts as an anode.

The apparatus may include provisions for agitating the electrolyte while the electric current is flowing.

The provisions for agitating may include provisions for causing flow of the volume of electrolyte solution to pass through the space defined between the flat conductive surface of the working electrode and the flat conductive surface of the counter electrode.

The organic electrolyte solution may be protic and the chemicals may include at least one of methanol, ethanol, isopropanol, ethylene glycol, and tetrahydrofurfuryl alcohol.

The organic electrolyte solution may be aprotic and the chemicals may include at least one of N-methylacetamide and acetonitrile.

The apparatus may include provisions for maintaining the organic electrolyte solution, the working electrode and the counter electrode at a constant temperature of between about 15 degrees Celsius to about 90 degrees Celsius.

The direct current source may include provisions for maintaining the electric current at a level at least sufficient to maintain oxide formation as oxide formation occurs and presents resistance to the electric current.

The apparatus may include provisions for terminating the flow of electric current when the flow of electric current meets a criterion.

The criterion may include a condition that the oxide layer has a pre-defined thickness,

The direct current source may include provisions for maintaining the electric current at a level to cause a current density of between about 1 mA/cm² to about 100 mA/cm² in the volume of organic electrolyte solution.

### Cathode Reaction

The oxide layer may be a metal oxide layer, the electrolyte solution may include at least one ionic source of metal and the direct current source may be operably configured to cause the electric current to flow in a direction in which the working electrode acts as a cathode.

The pre-defined volume of the electrolyte solution may be sufficient to ensure the flat conductive surface of the counter electrode and the flat conductive surface of the working electrode will be in contact with the electrolyte solution. The pre-defined volume may have a concentration of metal ions sufficient to plate the metal oxide onto the flat conductive surface of the working electrode to a desired thickness of the metal oxide layer.

The metal oxide layer may include aluminum oxide and the ionic source of metal may include at least one dissolved aluminum salt or at least one aluminate or a combination of the at least one dissolved aluminum salt or at least one aluminate.

The metal oxide layer may include indium oxide and the ionic source of metal may include at least one dissolved indium salt.

The metal oxide layer may include zinc oxide and the ionic source of metal may include at least one dissolved zinc salt or at least one zincate or a combination of the at least one dissolved zinc salt or at least one zincate.

The metal oxide layer may include aluminum-doped zinc oxide and the ionic source of metal may include at least one dissolved zinc salt and at least one dissolved aluminum salt.

The metal oxide layer may include indium-doped zinc oxide and the ionic source of metal may include at least one dissolved zinc salt and at least one dissolved indium salt.

The metal oxide layer may include chlorine-doped zinc oxide and the ionic source of metal includes at least one dissolved zinc salt and the organic electrolyte solution may include at least one dissolved chloride.

The metal oxide layer may include tin-doped indium oxide and the ionic source of metal may include at least one dissolved indium salt and at least one dissolved tin salt.

The organic electrolyte solution may be maintained still while the electric current is flowing.

The organic electrolyte solution may be protic and the chemicals may include at least one of methanol, ethanol, propanol, isopropanol, ethylene glycol, and glycerol.

The organic electrolyte solution may be aprotic and the chemicals may include at least one of dimethylsulfoxide (DMSO) and propylene carbonate.

The apparatus may include provisions for maintaining the organic electrolyte solution, the working electrode and the counter electrode at a temperature between about 15 degrees Celsius to about 90 degrees Celsius.

The apparatus may include provisions for terminating the flow of electric current when a pre-defined number of coulombs has passed through the organic electrolyte solution.

The pre-defined number of coulombs may be sufficient to cause substantially all of the ionic source of metal in the organic electrolyte solution to be depleted from the organic electrolyte solution and oxidized on the flat conductive surface of the working electrode to facilitate producing the oxide layer to a desired thickness.

The provisions for maintaining the electric current at a level may include provisions for maintaining the electric current at a level that produces a current density of between about 0.1 mA/cm² to about 100 mA/cm² in the organic electrolyte solution.

The provisions for maintaining the electric current may include provisions for maintaining the electric current at a level that produces an electric current concentration in the organic electrolyte solution between about 100 mA/cm³ to about 1000 mA/cm³.

The apparatus may include provisions for draining the organic electrolyte solution substantially depleted of the metal ions after the flat conductive surface of the cathode has been plated by the metal oxide to the desired thickness.

### Anodic Reaction Applied to Semiconductor Wafers

The working electrode may include a semiconductor wafer, the flat conductive surface may be on a front side or a back side of the semiconductor wafer and the oxide layer may be a semiconductor oxide layer. The semiconductor oxide layer may be formed directly on the flat conductive surface of the working electrode or may be formed through a metal oxide layer already formed thereon.

The semiconductor wafer may include an n-type crystalline semiconductor wafer or a p-type crystalline semiconductor wafer.

The flat conductive surface may be on an n-type portion or a p-type portion of the crystalline semiconductor wafer or the flat conductive surface may be on a metal oxide layer on an n-type portion or a p-type portion of the crystalline semiconductor wafer.

The apparatus may further include provisions for exposing the flat conductive surface of the working electrode to light for at least a portion of a time during which the electric current is flowing.

The provisions for exposing the flat conductive surface of the working electrode to light may include provisions for admitting light into the space between the flat conductive surface of the working electrode and the flat conductive surface of the counter electrode.

The provisions for admitting light into the space may include light transmissive portions in the counter electrode to permit light to pass through the light transmissive portions and impinge upon the flat conductive surface of the working electrode.

The provisions for admitting light may include a light-transmissive portion formed in the container for admitting light into the space through at least a portion of at least one peripheral edge of the space.

### Cathodic Reaction Applied to Semiconductor Wafers

The working electrode may be a semiconductor wafer, the flat conductive surface of the working electrode may be on a front side or a back side of the semiconductor wafer and the oxide may be a metal oxide. The metal oxide may be formed directly on the flat conductive surface or may be formed on a semiconductor oxide layer already on the flat conductive surface. The flat conductive surface of the working electrode may be on a semiconductor oxide layer on a front side or rear side of the semiconductor wafer.

The flat conductive surface of the working electrode semiconductor wafer may include an n-type portion or a p-type portion of a crystalline silicon photovoltaic cell.

The apparatus may further include provisions for exposing the flat conductive surface of the working electrode to light for at least a portion of a time during which the electric current is flowing.

The provisions for exposing the flat conductive surface of the working electrode to light may include provisions for admitting light into the space between the flat conductive surface of the working electrode and the flat conductive surface of the counter electrode.

The provisions for admitting light into the space may include light transmissive portions in the counter electrode to permit light to pass through the light transmissive portions and impinge upon the flat conductive surface of the working electrode.

The provisions for admitting light may include a light-transmissive portion formed in the container for admitting light into the space through at least a portion of at least one peripheral edge of the space.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is a simplified oblique view of an apparatus for forming an oxide layer on a flat conductive surface, according to a first embodiment of the invention;

FIG. 2 is a cross sectional view of a portion of the apparatus shown in FIG. 1 with a holder shown in a position in which oxide formation is operable to occur;

FIG. 3 is a top plan view of a container portion of the apparatus shown in FIG. 1;

FIG. 4 is a bottom oblique view of the container portion shown in FIG. 2;

FIG. 5 is a top simplified oblique view of a working electrode holder of the apparatus shown in FIG. 1;

FIG. 6 is a bottom view of the working electrode holder shown in FIG. 4;

FIG. 7 is a simplified cross sectional view of the working electrode holder shown in FIG. 4 holding a plate having a flat conductive surface on which an oxide layer is to be formed;

FIG. 8 is a cross sectional view of a portion of the apparatus shown in FIG. 1 with a holder shown in an alternate position in which an oxide layer can be formed;

FIG. 9 is a simplified cross sectional view of a portion of an apparatus according to a second embodiment for forming an oxide layer onto a p-type semiconductor surface;

FIG. 10 is a simplified cross sectional view of a portion of an apparatus according to a third embodiment, for forming an oxide layer onto a p-type semiconductor surface.

### DETAILED DESCRIPTION

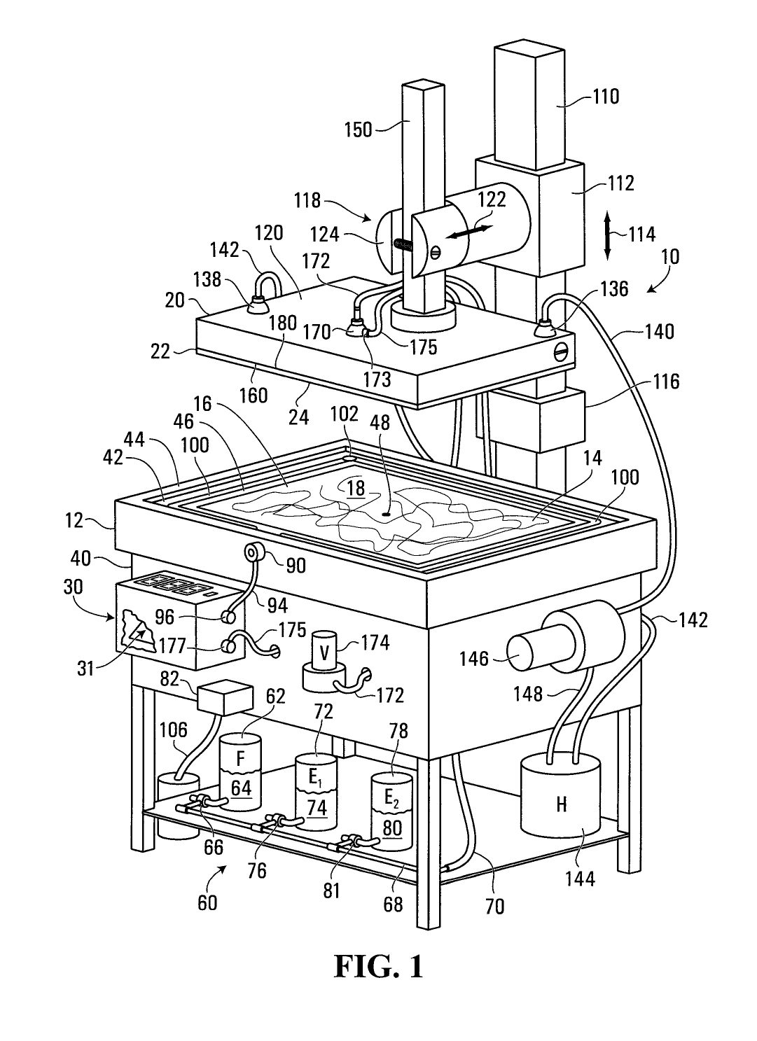

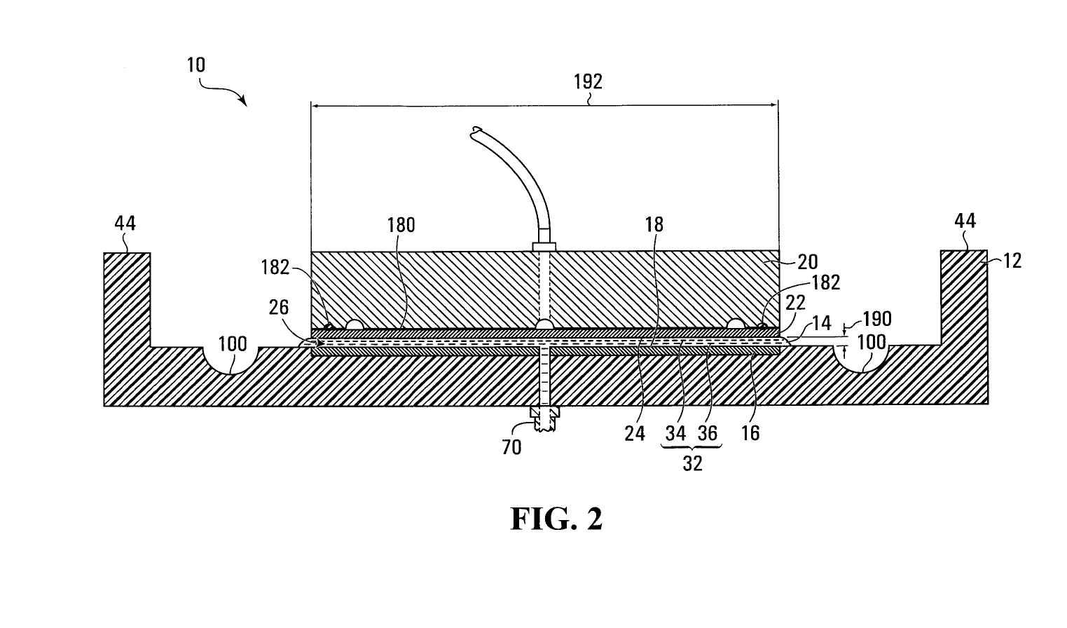

Referring to FIG. 1, an apparatus for forming an oxide layer on a flat conductive surface is shown generally at 10. Referring to FIGS. 1 and 2, the apparatus 10, includes a container 12 operably configured to hold a volume 14 of organic electrolyte solution containing chemicals for forming the oxide layer. The apparatus further includes a counter electrode 16 having a flat conductive surface 18 in a generally horizontal orientation in the container 12 such that the volume 14 of organic electrolyte solution floods the flat conductive surface 18 of the counter electrode 16.

The apparatus 10 further includes a working electrode holder 20 for holding a working electrode 22 bearing a flat conductive surface 24 onto which the oxide layer is to be formed. Referring to FIG. 2, the working electrode holder 20 holds the working electrode 22 in a generally horizontal orientation opposite, parallel and spaced apart from the counter electrode 16. A space 26 is thus defined between the flat conductive surface 18 of the counter electrode 16 and the flat conductive surface 24 of the working electrode 22. At least some of the volume 14 of organic electrolyte solution occupies the space 26 and is provided in sufficient quantity to simultaneously contact the flat conductive surface 18 of the counter electrode 16 and the flat conductive surface 24 of the working electrode 22.

Referring back to FIG. 1, the apparatus 10 further includes a direct current source 30 operably configured to be connected to the counter electrode 16 and the working electrode 22 to cause an electric current to flow between the counter electrode and the working electrode to cause the working electrode to selectively act as an anode or as a cathode in contact with the volume of organic electrolyte solution. A polarity of the direct current source 30 determines whether the working electrode 22 acts as an anode or as a cathode.

The working electrode 22 may be made of any conductive material capable of reacting with oxygen to form an oxide on the flat conductive surface 24 thereof. An oxide of the material of the working electrode 22 may be referred to as a simple oxide. If the working electrode 22 were an iron plate, for example the simple oxide would be an iron oxide. If the working electrode 22 were a crystalline semiconductor wafer, the simple oxide would be a silicon oxide. A simple oxide can be formed by causing the polarity of the working electrode 22 to be at a positive potential relative to the counter electrode 16.

Similarly, a metal oxide can be formed on the flat conductive surface 24 of the working electrode 22 by causing the polarity of the direct current source 30 to be set such that the working electrode has a negative polarity relative to the counter electrode 16. Different organic electrolyte solutions are used depending on whether a simple oxide or a metal oxide is to be formed on the flat conductive surface 24.

In the embodiment described the working electrode 22 is a semiconductor wafer, and the apparatus is used to form a semiconductor oxide on the flat conductive surface 24 of the semiconductor material itself or under a metal oxide layer already formed on the semiconductor material, by causing the polarity of the direct current source 30 to be such that the working electrode 22 has a positive potential relative to the counter electrode 16. Alternatively, a metal oxide layer can be formed on the flat conductive surface 24 of the working electrode 22 or on a semiconductor oxide layer already formed on the flat conductive surface of the working electrode, by causing the polarity of the direct current source 30 to be set such that the counter electrode 16 has a positive potential relative to the working electrode 22. Different organic electrolyte solutions are used depending on whether a semiconductor oxide or a metal oxide is to be formed on the flat conductive surface 24

Referring to FIG. 2, regardless of whether a simple oxide layer is to be formed or a metal oxide layer is to be formed, the volume 14 of electrolyte solution includes chemicals 32 that facilitate an electrolytic reaction and the chemicals include a source of oxygen 34. Where a metal oxide layer is to be formed, the chemicals include a source of oxygen and further include an ionic source of metal 36.

Referring back to FIG. 1, the apparatus 10 is described in more detail. In the embodiment shown, the container 12 is formed as a top portion of a table 40. The container 12 is generally rectangular in shape and has a bottom portion 42 and a perimeter upstanding wall 44 extending upwardly from a perimeter of the bottom portion 42. The bottom portion 42 and the perimeter upstanding wall 44 are formed of a chemically resistant material such as Teflon, polycarbonate, polystyrene or glass, for example.

The bottom portion 42 is formed with a rectangular recess 46 for receiving and holding the counter electrode 16. The counter electrode 16 is formed of a carbon graphite plate or glass graphite plate or graphite fabric material or a platinum plate, for example and has a flat conductive surface 18. The recess 46 is formed in the bottom portion 42 such that the flat conductive surface 18 of the counter electrode 16 is generally coplanar with the bottom portion 42 which, in the embodiment shown, is generally horizontally oriented.

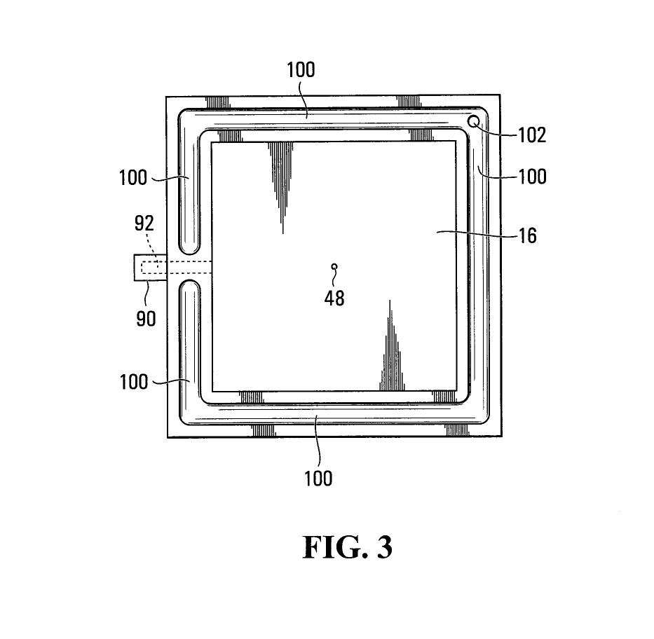

Referring to FIG. 3, the counter electrode 16 is connected to a connector 90 by a conductor 92 to facilitate easy electrical connection to the counter electrode 16. Referring back to FIG. 1, the connector 90 is connected by a wire 94 to a corresponding connector 96 of the direct current source 30. The working electrode 22 is similarly connected to the direct current source 30. Thus, the working electrode 22, the volume 14 of electrolyte solution and the counter electrode 16 form a series circuit with the current source 30. Thus, the direct current source 30 provides a direct current (DC) supply and includes an automatic control circuit 31 that can selectively adjust the polarity of an electric potential applied across the counter electrode 16 and the working electrode 22 and which can adjust the potential to increase, decrease or maintain an amount of electric current passing through the series circuit including the working electrode 22, the volume 14 of electrolyte solution and the counter electrode 16. In addition, the automatic control circuit 31 can determine whether or not a certain criterion is met such as whether or not the resistance of the series circuit has reached a level at which a pre-defined current flows in the series circuit, at which time the automatic control circuit 31 selectively shuts off the current source.

### Dispensing System

The counter electrode 16 has a centrally disposed opening 48 and the bottom portion 42 of the container 12 has an aligned opening (not shown) aligned with the centrally disposed opening 48, operable to admit the volume 14 of organic electrolyte solution into the container 12.

The volume 14 of electrolyte solution is provided by a dispensing system shown generally at 60. In the embodiment shown the dispensing system 60 comprises a first reservoir 62 operably configured to hold a flushing solution 64, and a first pump 66 for pumping a first volume of the flushing solution from the first reservoir into feed conduit 68 coupled by a flexible feed conduit 70 to the opening 48.

The dispensing system 60 further includes a second reservoir 72 operably configured to hold a first electrolyte solution 74 and a second pump 76 for pumping a pre-defined volume of the first electrolyte solution 74 from the second reservoir 72 into the feed conduit 68 and through the opening 48.

The dispensing system 60 further includes a third reservoir 78 operably configured to hold a second electrolyte solution 80 and a third pump 81 for pumping a pre-defined volume of the second electrolyte solution 80 from the third reservoir 78 into the feed conduit 68 and through the opening 48.

A controller 82 is provided to selectively operate the first, second or third pump (66, 76, 81) to selectively pump the flushing solution 64 or a pre-defined volume of the first or second electrolyte solutions (74, 80) into the feed conduit 50 and through the opening 48, to flood the flat conductive surface 18 of the counter electrode 16 so it can be used as part of an electrolytic cell with the working electrode 22 in the container 12.

The flushing solution 64 may include an organic solvent or water, for example.

The first and second electrolyte solutions 74, 80 are configured to facilitate use of the working electrode 22 as either an anode or a cathode, respectively, to suit the type of oxide layer to be formed. Each of the first and second electrolyte solutions 74, 80 includes chemicals including a source of oxygen sufficient to permit the oxide layer to be formed to a desired thickness. The source of oxygen may include dissolved oxygen or at least one oxygen precursor such as at least one of dissolved nitrate, nitrite, hydrogen peroxide and traces of water. The concentration of dissolved oxygen precursor ready for use in the electrochemical process of forming the oxide layer should be selected such that at least enough source oxygen is provided in the volume of electrolyte dispensed into the container 12 to facilitate formation of an oxide layer of a desired thickness.

The controller 82 selectively causes a first pre-defined volume of the first electrolyte solution 74 to be admitted into the container 12 and to cause the current source 30 to be configured to cause the working electrode 22 to act as an anode. The first pre-defined volume must be sufficient to ensure the flat conductive surface 18 of the counter electrode 16 and the flat conductive surface 24 of the working electrode 22 are in contact with the first pre-defined volume of the first electrolyte solution 74. With the working electrode 22 acting as an anode, the oxide formed on the flat conductive surface 24 of the working electrode 22 will be an oxide of the material of which the working electrode is made, i.e. a simple oxide Thus, for example, if the working electrode 22 is a crystalline silicon semiconductor wafer, a silicon oxide layer can be formed on the flat conductive surface thereof, or under a metal oxide layer already formed thereon, when the first electrolyte solution 74 is used and the current source 30 causes the working electrode 22 to have a positive potential relative to the counter electrode 16.

Where the working electrode 22 is used as an anode, the organic electrolyte solution may be protic and the chemicals in the first electrolyte solution 74 may include at least one of methanol, ethanol, isopropanol, ethylene glycol, and tetrahydrofurfuryl alcohol. Alternatively, the first electrolyte solution 74 may be a protic and the chemicals may include at least one of N-methylacetamide and acetonitrile.

Similarly, the controller 82 may alternatively operate the third pump 81 to cause a second pre-defined volume of the second electrolyte solution 80 to be admitted into the container 12 and to cause the current source 30 to be configured to cause the working electrode 22 to act as a cathode. The second pre-defined volume of the second electrolyte solution 80, must be sufficient to ensure the flat conductive surface 18 of the counter electrode 16 and the flat conductive surface 24 of the working electrode 22 are in contact with the second pre-defined volume of the second electrolyte solution 80.

In this embodiment where the working electrode 22 is a crystalline silicon semiconductor wafer, a metal oxide layer will be formed on the flat conductive surface 24 thereof or on a semiconductor oxide layer already formed on the flat conductive surface thereof, when the second electrolyte solution 80 is used and the current source 30 causes the working electrode 22 to have a negative potential relative to the counter electrode 16.

The second electrolyte solution 80 may be protic and the chemicals may include at least one of methanol, ethanol, propanol, isopropanol, ethylene glycol, and glycerol. Alternatively, the second electrolyte solution 80 may be aprotic and the chemicals may include at least one of dimethylsulfoxide (DMSO) and propylene carbonate.

Also, the second electrolyte solution 80 includes at least one ionic source of metal to facilitate the formation of a metal oxide layer on the flat conductive surface 24 of the working electrode 22 or on a simple oxide layer already formed on the flat conductive surface 24. The amount of ionic source of metal in the second pre-defined volume must be sufficient to facilitate formation of the metal oxide layer on the flat conductive surface 24 of the working electrode 22 to a desired thickness.

Where an aluminum oxide layer is intended to be formed on a PV cell, for example, the ionic source of metal may include at least one dissolved aluminum salt or at least one aluminate or a combination of the at least one dissolved aluminum salt or at least one aluminate. The dissolved aluminium salt may be selected from nitrate, chloride, or sulphate for example. The organic electrolyte solution may contain from 0.0001 Eq/L (gram equivalent/litre) to 0.1 Eq/L of aluminum or from 0.0001 Eq/L of aluminum to concentration of saturated solution to produce an aluminum oxide film having a thickness of about 10 nm to about 200 nm on a photovoltaic (PV) cell 4 in-8 in (10.16 cm-20.32 cm) square.

Where an indium oxide layer is to be formed on a PV cell the ionic source of metal may include at least one dissolved indium salt. The at least one dissolved indium salt may be selected from nitrate, chloride, or sulphate for example. The organic electrolyte solution may contain from 0.0001 Eq/L (gram equivalent/litre) to 0.1 Eq/L of indium or from 0.0001 Eq/L of indium to concentration of saturated solution to produce an indium oxide film having a thickness of about 50 nm to about 130 nm on a PV cell 4 in-8 in (10.16 cm-20.32 cm) square.

Where a zinc oxide layer is to be formed on a PV cell, the ionic source of metal may include at least one dissolved zinc salt or at least one zincate or a combination of the at least one dissolved zinc salt or at least one zincate. The at least one dissolved zinc salt may be selected from nitrate, chloride, or sulphate for example. The organic electrolyte solution may contain from 0.0001 Eq/L (gram equivalent/litre) to 0.1 Eq/L of zinc or from 0.0001 Eq/L of zinc to concentration of saturated solution to produce a zinc oxide film having a thickness of about 50 nm to about 130 nm on a PV cell 4 in-8 in (10.16 cm-20.32 cm) square.

Where an aluminum-doped zinc oxide layer is to be formed on a PV cell, the ionic source of metal may include at least one dissolved zinc salt and at least one dissolved aluminum salt. The dissolved zinc salt may be selected from nitrate, chloride, or sulphate for example. The dissolved aluminum salt may be selected from nitrate, chloride, or sulphate for example. The organic electrolyte solution may contain gram equivalents of zinc and aluminum in the ratio of between about 500/1 to 3:1 to produce an aluminium-doped zinc oxide film having a thickness of about 80 nm to about 100 nm on a PV cell 4 in-8 in (10.16 cm-20.32 cm)square.

Where an indium-doped zinc oxide layer is to be formed on a PV cell, the ionic source of metal may include at least one dissolved zinc salt and at least one dissolved indium salt. The dissolved zinc salt may be selected from nitrate, chloride, or sulphate for example, and the at least one dissolved indium salt, may be selected from nitrate, chloride, or sulphate for example. The organic electrolyte solution may contain gram equivalents of zinc and indium in the ratio of between about 200/1 to 5:1 to produce an indium-doped zinc oxide film having a thickness of about 50 nm to about 130 nm on a PV cell 4 in-8 in (10.16 cm-20.32 cm)square.

Where a chlorine-doped zinc oxide layer is to be formed on a PV cell, the ionic source of metal may include at least one dissolved zinc salt and at least one dissolved chloride. The at least one zinc salt may be selected from nitrate, chloride, or sulphate for example. The organic electrolyte solution may contain from 0.0001 Eq/L (gram equivalent/litre) to 0.1 Eq/L of zinc or from 0.0001 Eq/L of zinc to concentration of saturated solution and from 0.001 Eq/L to 0.1 Eq/L of chloride or from 0.001 Eq/L of chloride to concentration of saturated solution to produce a chlorine-doped zinc oxide film having a thickness of about 50 nm to about 130 nm on a PV cell 4 in-8 in (10.16 cm-20.32 cm) square.

Where a tin-doped indium oxide layer is to be formed on a PV cell, the ionic source of metal may include at least one dissolved indium salt and at least one dissolved tin salt. The dissolved indium salt may be selected from nitrate, chloride, or sulphate for example, and the at least one dissolved tin salt may be selected from nitrate, chloride, or sulphate for example. The organic electrolyte solution may contain gram equivalents of indium and tin in the ratio of between about 200/1 to 1:1 to produce a tin-doped indium oxide film having a thickness of about 50 nm to about 130 nm on a PV cell 4 in-8 in (10.16 cm-20.32 cm)square.

The controller 82 and the direct current source 30 are in communication with each other to ensure that the first pre-defined volume of the first electrolyte solution 74 is admitted into the container 12 prior to causing an electric current to flow in a direction in which the working electrode 22 acts as an anode and to ensure that the second pre-defined volume of the second electrolyte solution 80 is admitted into the container 12 prior to causing an electric current to flow in a direction in which the working electrode 22 acts as a cathode, and to ensure that the container 12 is flushed with flushing solution 64 prior to and between successive uses and so that with each successive use a new predefined volume of either the first or second electrolyte solutions 74 or 80 is admitted into the container 12, without contamination from a previous use.

Referring back to FIG. 3, to facilitate flushing the container of spent electrolyte solution, the bottom portion 42 of the container 12 has drainage channels 100 extending along perimeter margins of the bottom portion, adjacent the counter electrode 16. The drainage channels 100 are in communication with a drain opening 102. The drainage channels 100 are suitably graded to direct liquid (i.e. the flushing solution 64, or the first or second electrolyte solutions 74 or 80 respectively) into the drain opening 102.

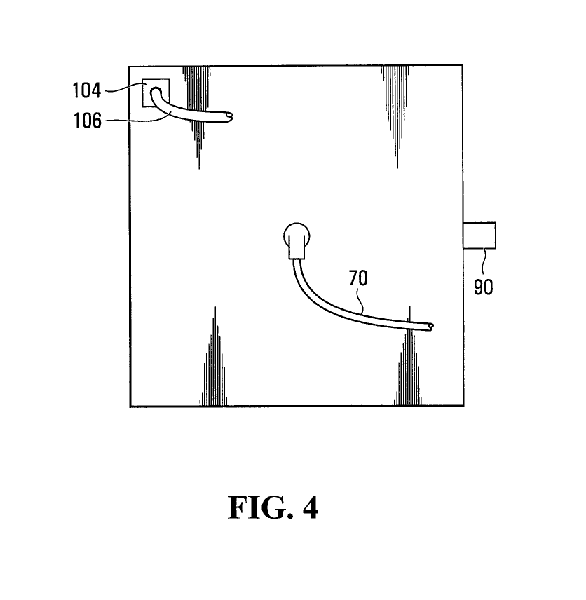

Referring to FIG. 4, a solenoid valve 104 is attached to the underside of the container 12 and is in communication with the drain opening 102 and with a drain conduit 106. The solenoid valve 104 is controlled by the controller (82 in FIG. 1) to be selectively opened and closed to drain flushing solution 64 or any first or second electrolyte solution (74, 80) from the container 12 or to contain flushing solution or the first or second electrolyte solution (74, 80) in the container 12, as desired. Thus, the solenoid valve 104 is kept closed when admitting the first or second electrolyte solution (74, 80) into the container 12 and during an electrolytic operation and is opened to drain spent electrolyte solution from the container 12 after an electrolytic operation and/or for flushing when flushing solution 64 is admitted into the container 12. The controller 82 drainage channels 100, drain opening 102, and solenoid valve 104 cooperate to drain electrolyte solution from the container 12 to a designated collector, after an electroplating cycle has been completed. Separate collectors may be provided to collect respective volumes of flushing solution 64, first electrolyte solution 74 and second electrolyte solution and a suitable valving system may be provided to selectively direct liquid received in the drain opening 102 to the appropriate collector.

Referring back to FIG. 1, the table 40 includes a support 110 that extends upwardly from the container 12. To the support 110 is connected a slidable collar 112 operable to slide on the support and relative to the support in a vertical direction indicated by arrow 114. A stop 116 may be securely fastened to the support 110 and may serve to limit the movement of the slidable collar 112 in the vertical direction. The slidable collar 112 is connected to a chuck mount 118 to which is fastened a working electrode holder 120. The mount 118 allows for movement of the working electrode holder 120 in the direction of arrow 122 generally in a direction perpendicular to the direction of movement of the slidable collar 162 indicated by arrow 114. The mount 118 has a clamp 124 for holding the working electrode holder 120 and which provides for vertical adjustment of the working electrode holder relative to the mount 118. Of course, robotics can alternatively be used to position the working electrode holder 120 in the locations described herein.

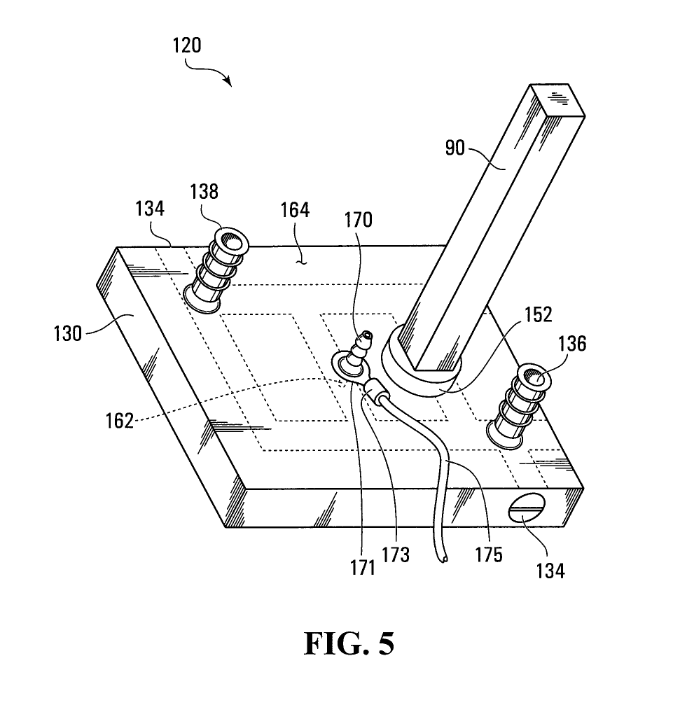

Referring to FIG. 5 in this embodiment, the apparatus includes provisions for maintaining the electrolyte solution, the working electrode 22 and the counter electrode 16 at a temperature between about 15 degrees Celsius to about 90 degrees Celsius with an accuracy of about +/−1 degree Celsius. These provisions include forming the working electrode holder 120 to include a conductive plate 130 which, in this embodiment, includes a metal plate of aluminium having a thickness of approximately 2 cm, but the plate could alternatively be made of stainless steel, silver or platinum or other metals or metal alloys, for example and it could have a different thickness. The plate 130 is formed to have a plurality of passages 132 sealed by plugs 134 and in communication with first and second tubing connectors 136 and 138 on a top surface 164 of the metal plate 130.

Referring back to FIG. 1, source and drain tubes 140 and 142 are connected to the first and second tubing connectors 136 and 138 respectively. The drain tube 142 is in communication with a liquid heater 144 and a pump 146 is in communication with the heater through a pump conduit 148. Operation of the pump 146 causes the pump to draw thermal liquid from the heater 91 through the pump conduit 148 and cause it to pass through the source tube 140 to the first tubing connector 136 and then through the passages 132 and out the second tubing connector 138 into the drain tube 142 and back to the liquid heater 144. The arrangement of the passages 132 and the tubing connectors 86 and 88 permits thermal fluid such as water to be pumped from the first tubing connector 86, through the passages 132 to the second tubing connector 88, for example, to provide for a flow of thermal fluid to be passed through the plate 80 to keep the working electrode 22 it holds at a generally constant temperature. The thermal fluid may be water or a 50/50 mixture of water and ethylene glycol antifreeze, for example. Other thermal fluids compatible with the metal used to form the plate 130 may alternatively be used. Or alternatively the plate 130 may be heated electrically.

Referring back to FIG. 5, the working electrode holder 120 has an upstanding member 150 fastened to the plate 130 by an electrically insulating mount 152, which electrically isolates the upstanding member 150 from the plate 130. Referring to FIG. 1, the upstanding member 150 is held by the clamp 124 to mount the working electrode holder 120 thereto.

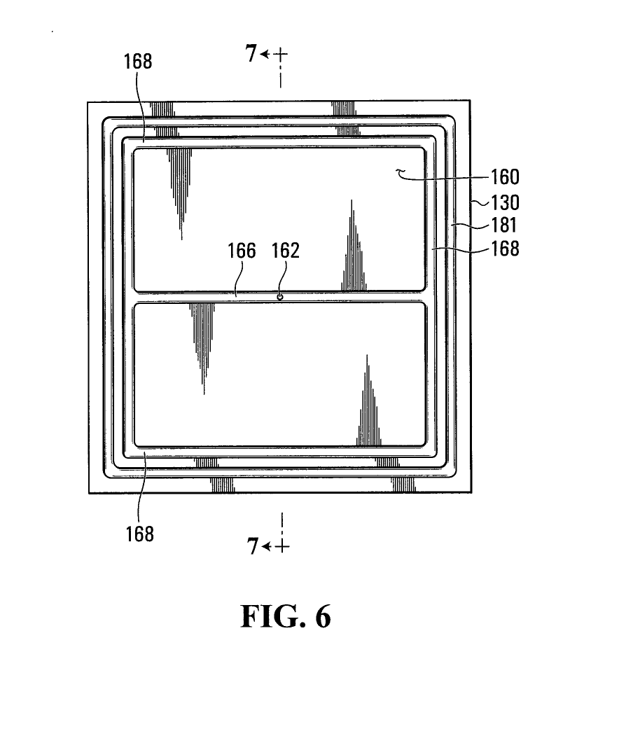

Referring to FIG. 6, an underside surface 160 of the plate 130 is shown. The plate has a bore 162 extending therethrough, between a top surface 164 of the plate as shown in FIG. 5 and the underside surface 160 of the plate as shown in FIG. 6. The underside surface 160 has a vacuum supply channel 166 cut therein (such as by a milling machine, for example) in communication with the bore 162 and in communication with a perimeter channel 168 extending around a perimeter margin of the underside surface 160. Referring to FIGS. 5 and 6, the bore 162 is in communication with a vacuum hose connector 170 which, referring to FIG. 1, is connected to a vacuum hose 172 connected to a vacuum pump 174 mounted on the table 40.

Referring to FIGS. 1 and 6, when the vacuum pump 174 is activated a vacuum is applied to the bore 162 and is communicated to the channels 166 and 168, particularly when a working electrode 22 is placed in the immediate vicinity of the underside surface 160.

Referring to FIG. 5, in the embodiment shown, the vacuum hose connector 170 is metallic and the plate 130 is metallic. The vacuum hose connector 170 has screw threads for connecting it to the plate 130 and since both the vacuum hose connector and the plate are metallic they are in electrical contact with each other. A ring 171 of an electrical terminal lug 173 is received on the screw threads of the vacuum hose connector 170 before screwing the vacuum hose connector into the bore 162 in the plate 130. Referring to FIGS. 1 and 5, a wire 175 connected to the electrical terminal lug 173 is electrically connected to a second terminal 177 of the direct current source 30. Use of the metallic plate 130 and the metallic vacuum hose connector 170 facilitates an easy electrical connection of the wire 175 to the plate 130. Of course, any other suitable method of connecting a wire to the plate could be used.

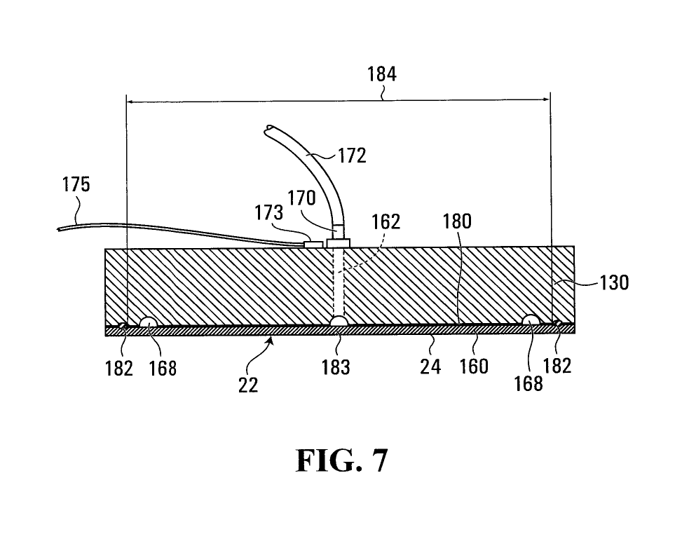

Referring to FIG. 6, the underside surface 160 also has a perimeter groove 181 which holds a rubber seal 182 formed of a soft rubber material such as silicone rubber, for example. An area 184 bounded by the perimeter groove 181 is intended to be the same shape as, but slightly smaller than the working electrode 22 to be held by the working electrode holder 120. The perimeter groove 181 is formed and the rubber seal 182 is sized to have a width between about 1 mm to 3 mm and a thickness between about 0.1 mm to about 1 mm such that the rubber seal protrudes no more than between about 0.1 mm to about 0.5 mm from the underside surface 160 of the plate 130, as seen best in FIG. 7. All surfaces of the plate 130, except the area 184 bounded by the perimeter groove and the rubber seal 182 are deeply-pre-anodized to protect these surfaces. This anodization forms an electrically insulative layer and causes these surfaces to be chemically inert to the first and second electrolyte solutions 74 and 78 and to the flushing solution 64. Alternatively, these surfaces can be pre-coated with an inert coating such as Teflon®, for example. Therefore, as explained below, the plate 130 is not involved in the electrochemical reactions that occur when the working electrode 22 and counter electrode 16 are placed in contact with the first or second electrolyte solutions 74 or 80 and current is conducted therethrough. The area 184 is not pre-anodized and remains conductive to facilitate electrical connection of the working electrode 22 to the plate 130.

Alternatively, a brass plate can be substituted for the aluminum plate 130. The surfaces of the brass plate that are exposed to the electrolyte may be coated with Teflon® or other coating chemically inert to the first and second electrolyte solutions 74, 80 and the flushing solution 64. Where a brass plate is used, the area 184 bounded by the perimeter groove 181 may be plated with silver, for example to provide for good electrical contact with the working electrode 22. The use of the brass plate may be best suited for a production version of the apparatus.

### Operation

Referring to FIGS. 1 and 7, to use the apparatus 10, an object on which an oxide layer is to be formed, is brought into the vicinity of the underside surface 160 of the plate 130 and then the vacuum pump 174 is activated. The object is intended to be generally flat planar in shape and in this embodiment is a semiconductor wafer or photovoltaic cell. In other embodiments other conductive or semiconductive planar objects may similarly act as the object. The term “conductive” as used herein in connection with the object onto which an oxide layer is to be formed is meant to include conductive and semiconductive materials.

The object has a back side surface 180 and bears the flat planar conductive surface 24 onto which the oxide layer will be formed, on a side of the object opposite the back side surface 180. The back side surface 180 is drawn into contact with the underside surface 160 of the plate 130 by the vacuum communicated to the channels 168 (and 166 shown in FIG. 6) through the bore 162. The vacuum communicated to the channels 166 and 168 creates a negative pressure between the back side surface 180 and the plate 130 such that the back side surface 180 is held pressed against the underside surface 160 of the plate 130 by ambient air pressure. The object should be suitably dimensioned and carefully positioned relative to the underside surface 160 prior to actuating the vacuum pump (174) such that the rubber seal 182 will contact the back side surface 180 closely adjacent an outer edge of the object, as shown in FIG. 7, such that most of the back side surface 180 is within the area 184 bounded by the rubber seal 182. The ambient air pressure presses the object tightly against the rubber seal 182 effectively sealing off the area 184 of the back side surface 180 bounded by the rubber seal 182. Thus, the rubber seal 182 will act to protect the area 184 of the back side surface 180 bounded by the rubber seal from contact with the electrolyte when the apparatus is in use.

Since the rubber seal 182 protrudes from the underside surface 160 by only a very small amount, and since the seal extends closely adjacent the perimeter edge of the object the object is held in a relatively flat planar condition, although a central interior portion 183 of the object will experience more vacuum because it is near the bore 162. The central interior portion 183 will flex and will be drawn into mechanical and electrical contact with the underside surface 160 of the plate 130. Since the plate 130 is in electrical contact with the second terminal 177 of the direct current source, when the object is in electrical contact with the underside surface 160 of the plate 130, it is also in electrical contact with the direct current source 30 through the wire 175 connected to the vacuum hose connector 170. With the object secured to and in electrical contact with the working electrode holder 120, the object becomes the working electrode 22.

Referring to FIGS. 1 and 2, with the working electrode 22 in place, the slidable collar 112 is slid down the support 110 until the flat conductive surface 24 of the working electrode 22 and the flat conductive surface 18 of the counter electrode 16 are parallel and spaced apart and define the space 26 therebetween. The counter electrode 16 and working electrode 22 are horizontally oriented, as are the flat conductive surface 18 of the counter electrode and the flat conductive surface 24 of the working electrode. In this embodiment, the working electrode 22 is positioned such that the flat conductive surface 24 of the working electrode is a distance 190 away from the flat conductive surface 18 of the counter electrode 16. The distance 190 may be between about 0.1% to about 20% of a length 192 of the working electrode 22, for example.

Where the working electrode 22 is a semiconductor wafer or photovoltaic cell for example, it may have the shape of a square rectangular plate having a side length of 15 cm, for example and thus the distance 190 may be pre-defined to be between about 0.15 mm to about 30 mm, for example. Desirably, the clamp 124 and slideable collar 112 are designed to provide for adjustment of the separation between the flat conductive surface 24 of the working electrode 22 and the flat conductive surface 18 of the counter electrode 16 within a range of about 0.15 mm to about 30 mm, to suit the size of the working electrode 22. The clamp 124 may be pre-set such that when the slidable collar 112 is resting on the stop 116, the pre-defined distance 190 is provided between the flat conductive surface 24 of the working electrode 22 and the flat conductive surface 18 of the counter electrode 16.

With the working electrode 22 positioned in close, parallel spaced apart relation as shown in FIG. 2, the controller 82 shown in FIG. 1 operates the first or second pump 76 or 81 to dispense a pre-defined volume of first or second electrolyte solution 74 or 80 into the space 26 between the flat conductive surface 18 of the counter electrode 16 and the flat conductive surface 24 of the working electrode 22 such that the flat conductive surface 18 is submerged in the electrolyte solution and substantially only the flat conductive surface 24 of the working electrode 22 is in contact with the electrolyte solution. The working electrode 22 is not entirely immersed in the organic electrolyte solution because the rubber seal 182 prevents the organic electrolyte solution from contacting the back side surface 180 of the working electrode 22. Furthermore, in the embodiment shown, because the flat conductive surface 18 of the counter electrode 16 and the flat conductive surface 24 of the working electrode 22 are so closely spaced apart, adhesion of the electrolyte to the flat conductive surface of the working electrode and the flat conductive surface of the counter electrode occurs due to capillary force of the electrolyte. Therefore, in this embodiment, only a small amount of electrolyte solution is required to facilitate the electrolytic reaction that will occur when current is passed through the electrolyte.

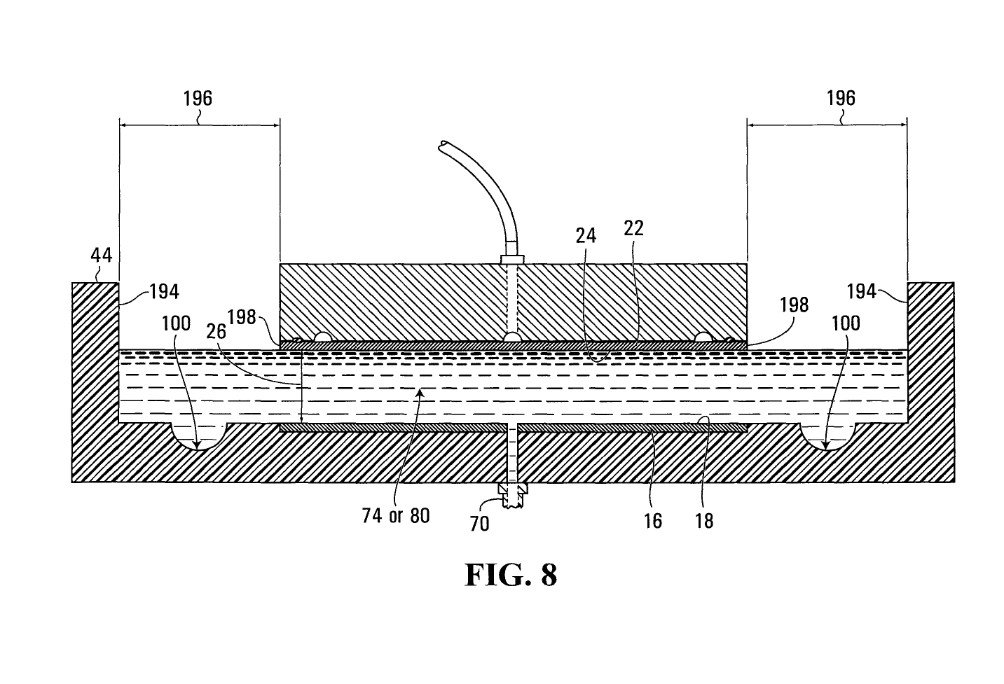

Alternatively, as shown in FIG. 8, a greater spacing may be employed between the flat conductive surface 24 of the working electrode 22 and the flat conductive surface 18 of the counter electrode 16, but in this embodiment, the capillary force of the electrolyte solution (74 or 80) does not maintain the electrolyte in the space between the flat conductive surface of the working electrode and the flat conductive surface of the counter electrode. This embodiment uses relatively more electrolyte solution (74 or 80). To keep the volume of electrolyte solution (74 or 80) used to a minimum, it may be desirable to make an inside surface 194 of the perimeter upstanding wall 44 just slightly larger than the working electrode 22. For example, the perimeter upstanding wall may be formed such that a distance 196 or spacing, between any edge 198 of the working electrode 22 and an inside surface 194 of an adjacent portion of the perimeter upstanding wall 44 may be between about 8 mm to about 10 mm or at least enough to accommodate the width of a drainage channel 100 between the edge 198 of the working electrode 22 and the inside surface 194 of an adjacent portion of the perimeter upstanding wall 44. Alternatively, the perimeter upstanding wall 44 can be undercut to provide space for drainage channels immediately adjacent to edge 198 of the working electrode 22 while occupying a space immediately above the drainage channels to keep the volume of electrolyte required to a minimum.

With the working electrode 22 positioned in the container 12 as shown in FIG. 7 or 8, the container is first flushed with flushing solution 64 to remove any contaminants. To do this, the controller 82 actuates the solenoid valve 104 to open it to facilitate draining and actuates the first pump 66 to pump a continuous stream of flushing solution through the opening 48 into the space 26 between the working electrode 22 and the counter electrode 16.

After flushing, the container 12 is ready to receive a volume of electrolyte solution. The specific electrolyte solution to be received in the container 12 is selected depending on whether a simple oxide layer comprising an oxide of the material of which the working electrode is made is intended to be formed on the conductive surface 24 or whether a metal oxide layer is intended to be formed on the conductive surface. Where the working electrode is a semiconductor wafer of PV cell and where a simple oxide layer is to be formed, the conductive surface 24 of the material forming the working electrode may be virgin or may already have a metallic oxide formed thereon. Where the working electrode is a semiconductor wafer or PV cell and where a metallic oxide layer is to be formed, the conductive surface 24 of the material forming the working electrode may be virgin or may already have a simple oxide layer formed thereon.

### Use of the Working Electrode as an Anode

Where the working electrode is a semiconductor wafer of PV cell and it is desired to form a simple oxide layer on a virgin conductive surface of the working electrode 22 or under a metal oxide layer already formed on the virgin conductive surface, the controller 82 actuates the second pump 76 to cause it to pump a first pre-defined volume of the first electrolyte solution 74 into the feed conduit 68, through the flexible feed conduit 70 and through the opening 48 formed in the counter electrode 16 such that the first pre-defined volume is admitted into the container 12 and some of the first pre-defined volume is in the space 26 and contained between the flat conductive surface 18 of the counter electrode 16 and the flat conductive surface 24 of the working electrode 22 and is in electrical contact therewith.

Where the spacing between the counter electrode 16 and the working electrode 22 is as shown in FIG. 2, the first pre-defined volume will be less than if the spacing were as shown in FIG. 8. Therefore the first electrolyte solution 74 will have to be configured to have a concentration of dissolved oxygen precursor suitable for use with the selected embodiment such that the first predefined volume will have enough dissolved oxygen to facilitate growth of the oxide layer at least to the desired thickness.

The back side surface 180 of the working electrode 22 is protected from exposure to the first electrolyte solution 74 by the seal 182 and thus virtually only the flat conductive surface 24 of the working electrode is exposed to the first electrolyte solution 74 and will participate in the electrolytic reaction. Since the surfaces of the plate 130 exposed to the electrolyte are pre-anodized or pre-coated with chemically resistant material the material of the plate does not participate in the electrolytic reaction.

With the flat conductive surface 24 of the working electrode 24 and the flat conductive surface 18 of the counter electrode 16 in contact with the first electrolyte solution 74, the controller 82 actuates the current source 30 such that the working electrode 22 is at a positive (+) potential relative to the counter electrode 16 which is at a negative (−) potential relative to the working electrode. This causes an electric current to flow through the first pre-defined volume of the first electrolyte solution 74 between the working electrode 22 and the counter electrode 16 and provides for electrochemical decomposition of the oxygen precursor. For example, if the oxygen precursor is water, the water is broken down into ions of hydrogen H⁺ and oxygen O²⁻. The oxygen ions migrate to the flat conductive surface 24 of the working electrode 22 and the surface oxidizes, thereby forming an oxide on the surface. At the same time the hydrogen ions migrate to the flat conductive surface 18 of the counter electrode 16, where they are reduced to form hydrogen gas H₂.

The depth of semiconductor oxide formation in the flat conductive surface 24 can be increased with increased potential between the working electrode and the counter electrode and with increased time and vice-versa and thus can be controlled by the automatic control circuit 31.

In the embodiment shown, the automatic control circuit 31 maintains the electric current at a level at least sufficient to maintain oxide formation as oxide formation occurs and presents increasing resistance to the electric current. For example, the automatic control circuit 31 may increase the potential between the working electrode 22 and the counter electrode 16 to maintain the current at a given level as the resistance presented by the forming semiconductor oxide layer increases. Or the automatic control circuit 31 may cause the current to increase or decrease as the oxide layer is formed. Knowing the voltage applied and the current being maintained the increasing resistance presented by the forming oxide layer is monitored by the automatic controller circuit 31 until a target resistance associated with a semiconductor oxide layer of a target thickness is reached at which time the automatic control circuit 31 shuts off the current source 30. Thus, in effect the automatic control circuit 31 terminates the flow of electric current when the current meets a criterion. In the embodiment described, the criterion is that the current must be impressed through a resistance of a target value indicative of a semiconductor oxide layer of a target thickness, for example.

Alternatively, the criterion may include a time measurement, wherein the criterion is met when the electric current has been applied at a defined level for a target amount of time indicative of development of a semiconductor oxide layer of a target thickness.

The automatic control circuit 31 may be configured to maintain the electric current at a level to cause a current density of between about 1 mA/cm² to about 100 mA/cm² in the first pre-defined volume of electrolyte solution 74, for example.

During formation of the semiconductor oxide layer on the working electrode 22, it is desirable to agitate the first pre-defined volume of the first electrolyte solution 74 while the electric current is flowing. Agitation may be provided by causing a flow in the first pre-defined volume of electrolyte solution 74 such that the electrolyte solution is not stagnant or still. This may be effected through the use of a vibrator on the table 40 to transfer vibratory movement to the counter electrode 16 and ultimately to the first pre-defined volume of electrolyte solution 74 in contact therewith such that a flow of the first pre-defined volume of electrolyte solution 74 passes through the space 26 defined between the flat conductive surface 24 of the working electrode 22 and the flat conductive surface 18 of the counter electrode 16. Alternatively, the container 12 may be configured with a circulation pump (not shown) to circulate the first pre-defined volume of electrolyte solution 74 through the space 26 defined between the flat conductive surface 24 of the working electrode 22 and the flat conductive surface 18 of the counter electrode 16.

As indicated earlier, desirably, the electrolyte solution 74, 80, working electrode 22 and the counter electrode 16 are maintained at a constant temperature of between about 15 degrees Celsius to about 90 degrees Celsius by maintaining the thermal fluid in the heater 144 at a temperature within this range and operating the pump 146 to pump the thermal fluid through the plate 130 of the working electrode holder 120.

Under the above conditions, a semiconductor oxide layer is formed on the flat conductive surface 24 of the working electrode 22. Once the semiconductor oxide layer has reached the desired thickness, the current source 30 is shut off and the controller 82 actuates the solenoid valve 104 and then actuates the first pump 66 to dispense a volume of flushing solution 64 through the bore 162 and into the container 12. Sustained dispensing of the flushing solution 64 flushes the spent first pre-defined volume of the first electrolyte solution 74 from the container 12 and into a catchment apparatus for recycling or at least de-toxification.

After a period of flushing, the working electrode 22 may then be raised out of the container 12 by the working electrode holder 120 and passed to separate material handling apparatus (not shown) for further processing such as annealing, for example. Alternatively, the separate material handling apparatus may simply turn the working electrode 22 upside down and start the above described process again, where the surface on which the semiconductor oxide layer was just formed becomes the back side surface 180 secured by the vacuum to the working electrode holder 120 and the side that was formerly the back side surface 180 is ready for a cycle of electrolytic action as described to form a semiconductor oxide layer on what was formerly the back side surface 180 of the working electrode.

Alternatively, the flat conductive surface that was just anodized by the process described above may be subjected to formation of a metal oxide layer as described below, on the semiconductor oxide layer just formed or the back side surface may be subjected to formation of a metal oxide layer as described below.

### Cathode Reaction

Where it is desired to form a metal oxide layer on a virgin conductive surface of the working electrode 22 or on a semiconductor oxide layer already formed on the virgin conductive surface, the controller 82 actuates the third pump 81 to cause it to pump a second pre-defined volume of the second electrolyte solution 80 into the feed conduit 68, through the flexible feed conduit 70 and through the opening 48 formed in the counter electrode 16 such that the second pre-defined volume is admitted into the container 12 such that some of second pre-defined volume is in the space 26 and is contained between the flat conductive surface 18 of the counter electrode 16 and the flat conductive surface 24 of the working electrode 22 and is in electrical contact therewith.

Where the spacing between the counter electrode 16 and the working electrode 22 is as shown in FIG. 2, the second pre-defined volume will be less than if the spacing were as shown in FIG. 8. Therefore the second electrolyte solution 80 will have to be configured to have a concentration of dissolved oxygen precursor suitable for use with the selected embodiment such that the second predefined volume will have enough dissolved oxygen precursor to facilitate growth of the metal oxide layer to the desired thickness.

In addition, the concentration of the source of metal in the second pre-defined volume of electrolyte solution 80 is selected such that when substantially all of the metal ions of the source of metal are depleted from the second pre-defined volume of electrolyte solution 80, the metal oxide formed on the surface of the flat conductive surface 24 of the working electrode 130 is of a thickness corresponding to the amount of the source of metal in the volume of electrolyte solution admitted into the container 12. Thus, to produce a suitable second electrolyte solution it will be necessary to determine how may moles of dissolved metal ions will be needed to form the metal oxide layer to have a target thickness and to ensure that at least this amount of dissolved metal ions are present in the second-predefined volume of second electrolyte solution 80.

The back side surface 180 of the working electrode 22 is protected from exposure to the second electrolyte solution 80 by the seal 182 and thus virtually only the flat conductive surface 24 of the working electrode is exposed to the second electrolyte solution 80 and will participate in the electrolytic reaction.

With the flat conductive surface 24 of the working electrode 22 and the flat conductive surface 18 of the counter electrode 16 in contact with the second electrolyte solution 80, the controller 82 actuates the current source 30 such that the working electrode 22 is at a negative (−) potential relative to the counter electrode 16 which is at a positive (+) potential relative to the working electrode 22. This causes an electric current to flow through the second pre-defined volume of the second electrolyte solution 80 between the working electrode 22 and the counter electrode 16 and provides a source of electrons for reduction of the dissolved oxygen or oxygen precursors and for interaction with metal ions dissolved in the solution in the vicinity of the conductive surface 24 of the working electrode 22. This results in precipitation of metal oxide directly onto the conductive surface 24 of the working electrode 22.

The rate of growth of metal oxide can be increased and decreased with increased or decreased current density in the second electrolyte solution 80 and thus can be controlled by the automatic control circuit 31. The rate of growth of metal oxide can also be controlled by the temperature of the second electrolyte solution 80.

As the number of metal ions in the second electrolyte precipitate as metal oxide on the flat conductive surface 24, the thickness of the metal oxide layer on the flat conductive surface increases and the second electrolyte solution becomes depleted of metal ions. When the second electrolyte solution is substantially depleted of metal ions, the metal oxide layer will have a particular thickness. To ensure substantially all of the metal ions have been depleted from the second electrolyte solution, it is necessary to provide a sufficient number of coulombs by way of the electric current. A coulomb meter may be used to measure the number of coulombs that have passed through the electrolyte or a time integral of the electrical current may be calculated to give the number of coulombs. Calibration curves plotting oxide layer thickness vs. coulombs or time at specified electric currents, metal ion concentrations and at different temperatures and for different surfaces, such as p-type or n-type crystalline semiconductor surfaces may be produced before production runs and used to determine suitable metal ion concentrations, temperatures, electric current and time parameters for production runs to produce metal oxide layers of desired thickness.

In the embodiment shown, the automatic control circuit 31 maintains the electric current at a level at least sufficient to maintain metal oxide formation as metal oxide layer formation occurs. The forming metal oxide layer may present resistance to the electric current. The automatic control circuit 31 may increase the potential between the working electrode 22 and the counter electrode 16 to maintain the current at a given level as the resistance presented by the forming metal oxide layer increases. Or, the automatic control circuit 31 may cause the current to increase or decrease as the metal oxide layer is formed. Regardless of whether the current is increased or decreased or maintained constant, the automatic control circuit 31 terminates the flow of electric current when a pre-defined number of coulombs has passed through the second electrolyte solution 80, the pre-defined number being sufficient to ensure that substantially all of the ionic source of metal in the second electrolyte solution has been depleted from the second electrolyte solution and oxidized on the flat conductive surface of the working electrode 22 to form the metal oxide layer to a desired thickness. In the embodiment described, the time integral of current is indicative of a pre-defined number of coulombs of electrons having passed through the second electrolyte solution 80, the pre-defined number of coulombs being indicative of a target thickness of the metal oxide layer.

The automatic control circuit 31 may control the electric current to produce a current density in the second pre-defined volume of second electrolyte solution on the order of about 0.1 mA/cm² to about 100 mA/cm². The optimum current density is selected in a range corresponding to preferable deposition of a specific metal oxide and elimination of a potential competitive reaction of metal deposition. For example, a suitable current density for deposition of aluminum oxide may be in a range of between about 1 mA/cm² to about 5 mA/cm².

In the embodiment shown in FIG. 2, high current concentrations in the range of about 1 mA/cm³ to about 1000 mA/cm³ and preferably in the range of about 10 mA/cm³ to about 100 mA/cm³ are possible due to the small separation distance 190 between the flat conductive surface 24 of the working electrode 22 and the flat conductive surface 18 of the counter electrode 16.

During formation of the metal oxide layer on the working electrode 22, it is desirable not to agitate the second pre-defined volume of the second electrolyte solution 80 while the electric current is flowing and to maintain the second pre-defined volume of the second electrolyte solution still.

As indicated earlier, desirably, the second pre-defined volume of the second electrolyte solution 80, the working electrode 22 and the counter electrode 16 are maintained at a constant temperature of between about 15 degrees Celsius to about 90 degrees Celsius by maintaining the thermal fluid in the heater 144 at a temperature within this range and operating the pump 146 to pump the thermal fluid through the plate 130 of the working electrode holder 120.

The thickness of the metal oxide layer formed on the flat conductive surface 24 is controlled by the amount of dissolved metal ions in the second electrolyte solution 80 subject to a sufficient number of coulombs of electrons passing through the second electrolyte solution 80. Thus, the number of moles of dissolved metal ions required to form the metal oxide layer to the desired thickness must first be determined and then the concentration of dissolved metal ions required in the second pre-defined volume of second electrolyte solution can be determined knowing that there must be sufficient volume to ensure the flat conductive surface 24 of the working electrode 22 and the flat conductive surface 18 of the counter electrode 16 will be in contact with the second electrolyte solution. This provides for very accurate control of the thickness of the metal oxide layer and provides for near 100% utilization of all metal ions in the second electrolyte solution 80.

When a sufficient number of coulombs has passed through the second electrolyte solution 80 and substantially all of the metal ions of the source of metal in the second pre-defined volume of second electrolyte solution 80 are depleted from the second electrolyte solution and formed on the flat conductive surface 24 of the working electrode 22 as a metal oxide film of the desired thickness, a resistance to electric current flow is presented by the metal oxide layer and this is detected by the automatic control circuit 31. In response the automatic control circuit 31 shuts off the current source 30. Once the current source 30 is shut off the controller 82 actuates the solenoid valve 104 and then actuates the first pump 66 to dispense a volume of flushing solution through the opening 48 and into the container 12. Sustained dispensing of the flushing solution flushes the spent second pre-defined volume of the second electrolyte solution from the container 12 and into a catchment apparatus for recycling or at least de-toxification.

The vacuum may then be released by switching off the vacuum pump 108 and dropping the working electrode 22, now having a metal oxide plated surface, onto material handling equipment (not shown) for further processing stages, such as annealing, for example.

After the working electrode 22 has been removed for further processing and the depleted electrolyte has been drained from the container 12, the apparatus 10 is then ready to receive another working electrode bearing a flat conductive surface on which a metal oxide is to be formed, or the working electrode 22 can be turned over and re-attached to the working electrode holder 120 by the surface on which the metal oxide layer was just formed and the back side surface 180 can be exposed for metal oxide layer formation according to the process above.

Using the above-described processes, a semiconductor oxide layer may be formed on a virgin semiconductor surface and a metal oxide layer may be formed on the semiconductor oxide layer. The formation of the metal oxide layer in this case should be done while the semiconductor oxide layer is still “wet” i.e. just formed and before any annealing.

Similarly, using the above processes a metal oxide layer can be formed directly on a virgin semiconductor surface and a semiconductor oxide layer may be formed after the metal oxide layer has been formed. The formation of the semiconductor oxide layer in this case should be done while the metal oxide layer is still “wet”.

It has been found that the semiconductor oxide layer penetrates the flat conductive surface and grows into that surface as the semiconductor oxide layer is formed. This occurs whether the semiconductor oxide layer is formed on a virgin surface of the semiconductor material or after a metal oxide layer has already been formed by the process described above, on the virgin surface.

It is also desirable to form the desired semiconductor oxide layer and metal oxide layer on the front and/or back surfaces before any annealing. Annealing is ultimately necessary to create the necessary crystal structure in the semiconductor oxide or metallic oxide resulting from the above process.

Depending on the chemical composition and thickness of the semiconductor oxide or plated metal oxide, annealing may be performed at temperatures in the range of about 300 degrees celcius to about 700 degrees celcius in an air atmosphere or in a special gas atmosphere. A special gas atmosphere for this purpose may include a gas comprised of about 3% to about 10% hydrogen balanced with nitrogen or inert gas, for example. The annealing process may take about 15 min to about 2 hours, for example.

The above apparatus is particularly well suited for forming metal oxides on semiconductor devices such as photovoltaic cells. In this case, the flat conductive surface 24 of the working electrode 22 is a surface of an n-type or p-type semiconductor substrate and the apparatus 10 is form a simple oxide film or a metal oxide film on the surface of the n-type or p-type semiconductor substrate. Such films may be used to passivate and to improve the optical qualities of the semiconductor substrate surface.

In one experiment, an aluminum oxide film was plated onto a p-type Si crystalline wafer using the process described above. The second electrolyte was a saturated solution of AlCl₃ in isopropanol. The electrolyte was held at a temperature of about 30 degrees Celsius and the current density was about 0.25 mA/cm² for 2 min. X-ray diffraction analysis (not shown) revealed a transition aluminum oxide in the form k-Al₂0₃ with typical peaks at 2θ₁=32.903 degrees (more intensive) and 2θ₂=32.092 (less intensive). The surface area of the working electrode 22 was 100 cm². The distance 190 between the flat conductive surface 24 of the working electrode 22 and the flat conductive surface 18 of the counter electrode 16 was 1 mm. The concentration of Aluminum ions was 0.005 Eq/L (gram equivalent/liter).

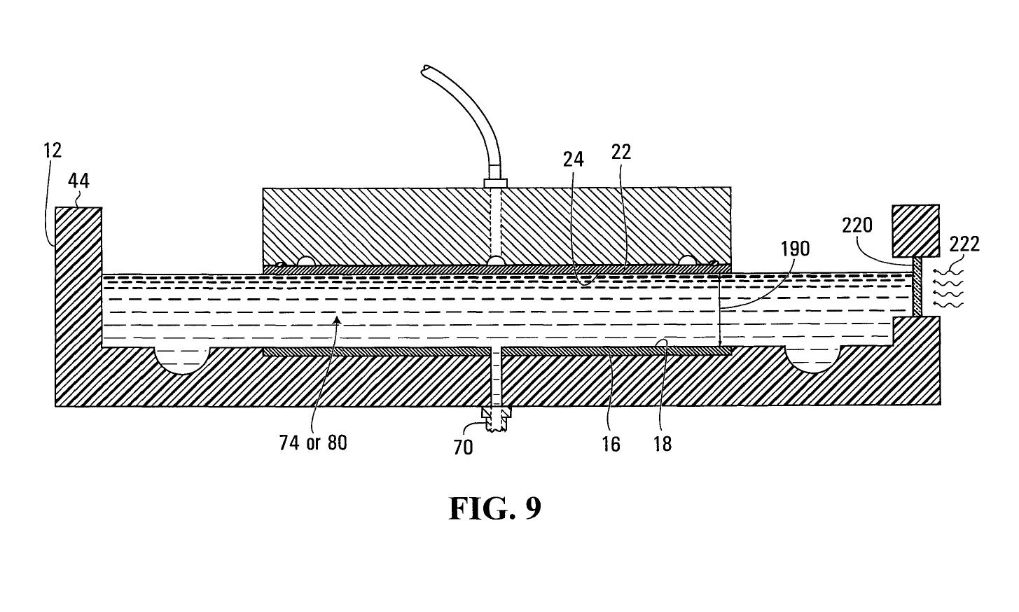

Referring to FIG. 9, where the working electrode 22 is a p-type semiconductor substrate and the direct current source causes current to flow such that the working electrode acts as a cathode, resulting in metal oxide plating on the flat conductive surface 24 or where the working electrode 22 is an n-type semiconductor substrate and the direct current source causes electric current to flow such that the working electrode functions as an anode resulting in the formation of a semiconductor oxide layer on the flat conductive surface, the oxide forming process can be enhanced by illuminating or admitting light onto the flat conductive surface 24 of the working electrode 22 while the electric current is flowing. To do this, the distance 190 between the flat conductive surface 24 of the working electrode 22 and the flat conductive surface 18 of the counter electrode 16 may be set to approximately 3 cm, for example and the volume of first or second electrolyte solution 74, 80 is increased to ensure that the flat conductive surface 24 and the flat conductive surface 18 are still in contact with the electrolyte solution. To achieve this, the perimeter upstanding wall 44 of the container 12 is increased in height and is provided with a light transparent window 220 formed of a glass of polystyrene, for example, for admitting light 222 produced by an external light source (not shown) to pass through the window 220, through the electrolyte solution 74, 80, and onto the flat conductive surface 24 of the working electrode 22.

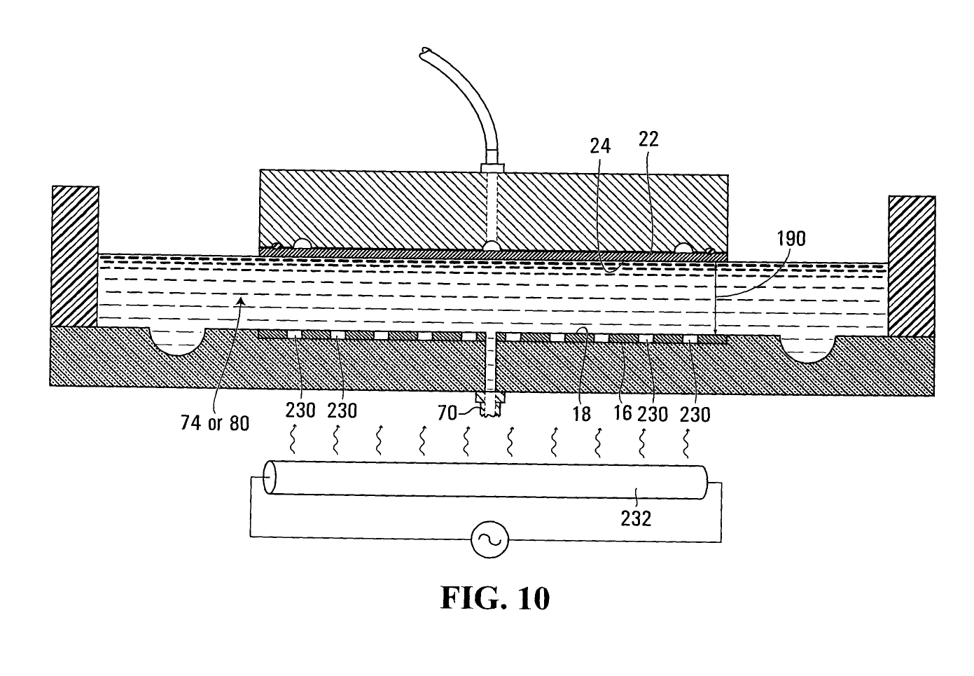

Referring to FIG. 10, in another embodiment the distance 190 may be decreased by providing openings such as shown at 230 in the counter electrode 16 and by causing the bottom portion 42 of the container 12 to be formed of a transparent material such as a glass of polystyrene, for example. A light source 232 may be placed beneath the container 12 such that light can pass though the bottom portion 42 of the container and through the openings 230 of the counter electrode 16 and through the volume of electrolyte solution to reach the flat conductive surface 24 of the working electrode 22.

The above apparatus and method provide for precision control over the distance between the flat conductive surface 24 of the working electrode 22 and the flat conductive surface 18 of the counter electrode 16, the amount of the electrolyte solution, and the amount of dissolved metal salts and other chemical components in the electrolyte solution. This enables precision control of the thickness of the semiconductor oxide or metal oxide formed on the surface of the object, which has particular advantages when the object is a semiconductor substrate for a PV cell, for example. In addition, since the distance between the flat conductive surface 24 of the working electrode 22 and the flat conductive surface 18 of the counter electrode 16 is relatively small, the resistance presented by the electrolyte solution is relatively small, which enables the use of low voltage while achieving high current densities which results in very low heat generation within the electrolyte solution producing only small convective movement within the electrolyte, which is particularly advantageous when forming metal oxides on the surface of semiconductors such as crystalline silicon wafers used for photovoltaic cells.

In addition, the above apparatus and methods avoid the use of separate electric insulation on the back side of the working electrode due to the sealing effect of the rubber seal on the working electrode holder, and the above method and apparatus provide for nearly 100% utilization of the metal ions in the volume of second electrolyte used in a given plating operation. Finally, the above apparatus and method allow the same apparatus to be selectively used for the formation of semiconductor oxides and metal oxides on the same conductive surface of a semiconductor wafer or a PV cell with only a change in electrolyte and a change in current direction.

While specific embodiments of the invention have been described and illustrated, such embodiments should be considered illustrative of the invention only and not as limiting the invention as construed in accordance with the accompanying claims.

1. A method of electrochemically forming an oxide layer on a flat conductive surface, the method comprising:
positioning a working electrode bearing the flat conductive surface in opposed parallel spaced apart relation to a flat conductive surface of a counter electrode such that said flat conductive surface of said working electrode and said flat conductive surface of said counter electrode are generally opposed, horizontally oriented, and define a space therebetween;
causing a volume of organic electrolyte solution containing chemicals for forming said oxide layer on said flat conductive surface of said working electrode to flood said flat conductive surface of said counter electrode surface and occupy the space defined between said flat conductive surface of said working electrode and said flat conductive surface of said counter electrode such that at least said flat conductive surface of said counter electrode is in contact with said organic electrolyte solution and substantially only the flat conductive surface of the working electrode is in contact with the organic electrolyte solution; and
causing an electric current to flow between substantially only the flat conductive surface of said counter electrode and substantially only the flat conductive surface of the working electrode, in the organic electrolyte solution, for a period of time and at a magnitude sufficient to cause said chemicals to form said oxide layer on said flat conductive surface of said working electrode.

2. The method of claim 1 wherein causing said volume of organic electrolyte solution to occupy the space defined between said flat counter electrode surface and said flat conductive surface of said working electrode comprises holding the working electrode such that substantially only the flat conductive surface of the working electrode is in contact with the organic electrolyte solution but the entire working electrode is not immersed in the organic electrolyte solution.

3. The method of claim 2 wherein holding comprises protecting a substantial portion of a side of said working electrode, opposite said flat conductive surface of said working electrode, from contact with said organic electrolyte solution.

4. The method of claim 3 wherein protecting comprises holding a rear side of said working electrode against a holding surface bearing a seal operably configured to contact said rear side of said working electrode adjacent an outer perimeter edge of said rear side of said working electrode.

5. The method of claim 4 wherein holding said working electrode against said holding surface comprises causing a negative pressure to occur adjacent said rear side of said working electrode so that ambient pressure presses said rear side of said working electrode against said seal.

6. The method of claim 5 wherein causing said negative pressure comprises providing a vacuum adjacent said seal.

7. The method of claim 1 wherein said flat conductive surface of said working electrode and said flat conductive surface of said counter electrode are spaced apart by a distance that facilitates adhesion of the organic electrolyte solution to the flat conductive surface of said working electrode and said flat conductive surface of said counter electrode due to capillary force of the organic electrolyte solution.

8. The method of claim 1 wherein positioning said working electrode comprises positioning said working electrode such that said flat conductive surface of said working electrode is between about 0.1% to about 20% of a length of said working electrode, from said flat conductive surface of said counter electrode.

9. The method of claim 1 wherein positioning said working electrode in relation to said flat conductive surface of said counter electrode comprises holding said counter electrode in a generally horizontal orientation in a container operably configured to hold said organic electrolyte solution and holding said working electrode in said container and spaced apart from said counter electrode such that said space is defined between said flat conductive surface of said working electrode and said flat conductive surface of said counter electrode.

10. The method of claim 9 wherein causing said volume of organic electrolyte solution to flood said flat conductive surface of said counter electrode comprises admitting a pre-defined volume of said organic electrolyte solution into said container.

11. The method of claim 10 wherein admitting the pre-defined volume of said organic electrolyte solution comprises passing said pre-defined volume through an opening in the counter electrode, the opening being in communication with the space between said flat conductive surface of said working electrode and said flat conductive surface of said counter electrode.

12. The method of claim 11 wherein passing said pre-defined volume through an opening comprises pumping said predefined volume of said organic electrolyte solution from a reservoir through said opening.

13. The method of claim 1 further comprising draining the organic electrolyte solution after said oxide layer is formed to a desired thickness on said flat conductive surface of said working electrode.

14. The method of claim 1 wherein said chemicals comprise a source of oxygen sufficient to permit said oxide layer to be formed to a desired thickness.

15. The method of claim 14 wherein said source of oxygen comprises dissolved oxygen or at least one oxygen precursor.

16. The method of claim 15 wherein said source of oxygen comprises at least one oxygen precursor and wherein the at least one oxygen precursor comprises at least one of dissolved nitrate, nitrite, hydrogen peroxide and traces of water.

17. The method of claim 14 wherein the working electrode is formed of a material and wherein the oxide layer is an oxide of said material and wherein causing said electric current to flow comprises causing said electric current to flow in a direction such that said working electrode acts as an anode.

18. The method of claim 1 further comprising agitating said organic electrolyte solution while said electric current is flowing.

19. The method of claim 18 wherein agitating comprises causing a flow of said organic electrolyte solution to pass through the space defined between said flat conductive surface of said working electrode and said flat conductive surface of said counter electrode.

20. The method of claim 17 wherein said organic electrolyte solution is protic and said chemicals include at least one of methanol, ethanol, isopropanol, ethylene glycol, and tetrahydrofurfuryl alcohol.

21. The method of claim 17 wherein said organic electrolyte solution is aprotic and said chemicals include at least one of N-methylacetamide and acetonitrile.

22. The method of claim 17 wherein said organic electrolyte solution and said working electrode and said counter electrode are generally maintained at a constant temperature of between about 15 degrees Celsius to about 90 degrees Celsius.

23. The method of claim 17 wherein causing said electric current to flow comprises maintaining said electric current at a level at least sufficient to maintain oxide formation on said working electrode as oxide formation occurs and presents resistance to said electric current.

24. The method of claim 17 further comprising terminating said flow of electric current when said flow of electric current meets a criterion.

25. The method of claim 24 wherein said criterion includes a condition that said oxide layer has a pre-defined thickness,

26. The method of claim 17 wherein said current has a current density of between about 1 mA/cm² to about 100 mA/cm² in the organic electrolyte solution.

27. The method of claim 1 wherein the oxide layer is a metal oxide layer and wherein causing said electric current to flow comprises causing said electric current to flow in a direction such that said working electrode acts as a cathode and wherein said organic electrolyte solution includes at least one ionic source of metal.

28. The method of claim 27 further comprising determining said pre-defined volume based on the desired thickness of the metal oxide desired to be plated onto said flat conductive surface of said cathode and based on a concentration of said ionic source of metal and a volume of said organic electrolyte solution.

29. The method of claim 27 wherein said oxide layer includes a metal oxide film comprising aluminum oxide and wherein said ionic source of metal comprises at least one dissolved aluminum salt or at least one aluminate or a combination of said at least one dissolved aluminum salt or at least one aluminate.

30. The method of claim 27 wherein said oxide layer includes a metal oxide film comprising indium oxide and wherein said ionic source of metal comprises at least one dissolved indium salt.

31. The method of claim 27 wherein said oxide layer includes a metal oxide film comprising zinc oxide and wherein said ionic source of metal comprises at least one dissolved zinc salt or at least one zincate or a combination of said at least one dissolved zinc salt or at least one zincate.

32. The method of claim 27 wherein said oxide layer includes a metal oxide film comprising aluminum-doped zinc oxide and wherein said ionic source of metal comprises at least one dissolved zinc salt and at least one dissolved aluminum salt.

33. The method of claim 27 wherein said oxide layer includes a metal oxide film comprising indium-doped zinc oxide and wherein said ionic source of metal comprises at least one dissolved zinc salt and at least one dissolved indium salt.

34. The method of claim 27 wherein said oxide layer includes a metal oxide film comprising chlorine-doped zinc oxide and wherein said ionic source of metal comprises at least one dissolved zinc salt and wherein said organic electrolyte solution comprises at least one dissolved chloride.

35. The method of claim 27 wherein said oxide layer includes a metal oxide film comprising tin-doped indium oxide and wherein said ionic source of metal comprises at least one dissolved indium salt and at least one dissolved tin salt.

36. The method of claim 27 further comprising maintaining said organic electrolyte solution still while said electric current is flowing.

37. The method of claim 27 wherein said organic electrolyte solution is protic and wherein said chemicals include at least one of methanol, ethanol, propanol, isopropanol, ethylene glycol, and glycerol.

38. The method of claim 27 wherein said organic electrolyte solution is aprotic and wherein said chemicals include at least one of dimethylsulfoxide (DMSO) and propylene carbonate.

39. The method of claim 27 wherein said organic electrolyte solution and said working electrode and said counter electrode are maintained at a temperature between about 15 degrees Celsius to about 90 degrees Celsius.

40. The method of claim 27 further comprising terminating said flow of electric current when a pre-defined number of coulombs has passed through said electrolyte solution.

41. The method of claim 40 wherein said pre-defined number of coulombs is sufficient to cause substantially all of said ionic source of metal in said electrolyte solution to be depleted from said organic electrolyte solution and oxidized on said flat conductive surface of said working electrode to facilitate producing said oxide layer to a desired thickness.

42. The method of claim 41 wherein maintaining said electric current at a level comprises maintaining said electric current at a level that produces a current density of between about 0.1 mA/cm² to about 100 mA/cm² in said organic electrolyte solution.

43. The method of claim 27 wherein said electric current is maintained at a level that produces an electric current concentration between about 1 mA/cm³ to about 1000 mA/cm³ in the organic electrolyte solution.

44. The method of claim 41 further comprising draining the organic electrolyte solution substantially depleted of said metal ions after said flat conductive surface of said cathode has been plated by said metal oxide to said desired thickness.

45. A method of forming an oxide layer on a semiconductor wafer, the method comprising the method of claim 1 wherein said working electrode comprises said semiconductor wafer, said flat conductive surface is on a front side or a back side of said semiconductor wafer and said oxide layer is a semiconductor oxide layer.

46. The method of claim 45 wherein said semiconductor wafer includes an n-type crystalline semiconductor wafer or a p-type crystalline semiconductor wafer.

47. The method of claim 46 wherein said flat conductive surface is on an n-type portion or a p-type portion of said crystalline semiconductor wafer or wherein said flat conductive surface is on a metal oxide layer on an n-type portion or a p-type portion of said crystalline semiconductor wafer.

48. The method of claim 46 wherein the method further includes exposing said flat conductive surface of said working electrode to light for at least a portion of a time during which said electric current is flowing.

49. The method of claim 48 wherein exposing said flat conductive surface of said working electrode to light comprises admitting light into said space between said flat conductive surface of said working electrode and said flat conductive surface of said counter electrode.

50. The method of claim 49 wherein admitting light into said space comprises admitting light through openings in said counter electrode or admitting light through at least a portion of at least one peripheral edge of said space.

51. A method of forming a metal oxide layer on a semiconductor wafer, the method comprising the method of claim 27 wherein said working electrode comprises said semiconductor wafer, said flat conductive surface of said working electrode is on a front side or a back side of said semiconductor wafer or wherein said flat conductive surface of said working electrode is on a semiconductor oxide layer on a front side or rear side of said semiconductor wafer.

52. The method of claim 51 wherein said flat conductive surface of said working electrode semiconductor wafer includes an n-type portion or a p-type portion of a crystalline silicon photovoltaic cell.

53. The method of claim 51 wherein the method further includes exposing the flat conductive surface of said working electrode to light for at least a portion of a time during which said electric current is flowing.

54. The method of claim 53 wherein exposing said flat conductive surface of said working electrode to light comprises admitting light into said space between said flat conductive surface of said working electrode and said flat conductive surface of said counter electrode.

55. The method of claim 54 wherein admitting light in said space comprises admitting light through openings in said counter electrode or admitting light through at least a portion of at least one peripheral edge of said space.

56. An apparatus for electrochemically forming an oxide layer on a flat conductive surface, the apparatus comprising:
a container operably configured to hold a volume of organic electrolyte solution containing chemicals for forming said oxide layer;
a counter electrode having a flat conductive surface in a generally horizontal orientation in said container such that said organic electrolyte solution floods said flat conductive surface of said counter electrode;
a working electrode holder for holding a working electrode bearing the flat conductive surface onto which said oxide layer is to be formed in a generally horizontal orientation opposite, parallel and spaced apart from said counter electrode such that a space is defined between said flat conductive surface of said counter electrode and said flat conductive surface of the working electrode, wherein at least some of said organic electrolyte solution can occupy said space and contact said flat conductive surface of said counter electrode and said flat conductive surface of the working electrode;
an direct current source operably configured to be connected to said counter electrode and the working electrode to cause an electric current to flow between said counter electrode and the working electrode to cause the working electrode to act as an anode or as a cathode in said at least some of said organic electrolyte solution.

57. The apparatus of claim 56 wherein the working electrode holder is operably configured to hold the working electrode such that substantially only the flat conductive surface of the working electrode is in contact with the organic electrolyte solution but the entire working electrode is not immersed in the organic electrolyte solution.

58. The apparatus of claim 57 wherein said working electrode holder includes a protector operably configured to protect a substantial portion of a side of the working electrode from contact with the organic electrolyte solution.

59. The apparatus of claim 58 wherein said protector includes a holding surface bearing a seal operably configured to contact a rear side of the working electrode adjacent an outer perimeter edge of the rear side of the working electrode.

60. The apparatus of claim 59 wherein said working electrode holder includes means for causing a negative pressure to occur adjacent the rear side of the working electrode so that ambient pressure presses the rear side of the working electrode against the seal with sufficient force to prevent leakage of said electrolyte solution past said seal.

61. The apparatus of claim 60 wherein said means for causing a negative pressure comprises a vacuum opening adjacent said seal.

62. The apparatus of claim 56 wherein said working electrode holder is operably configured to space said flat conductive surface of the working electrode from said flat conductive surface of said counter electrode by a distance that facilitates adhesion of the organic electrolyte solution to the flat conductive surface of the working electrode and said flat conductive surface of said counter electrode due to capillary force of the organic electrolyte solution.

63. The apparatus of claim 56 wherein said working electrode holder is operably configured to position the working electrode such that said flat conductive surface of the working electrode is between about 0.1% to about 20% of a length of the working electrode, from said flat conductive surface of said counter electrode.

64. The apparatus of claim 56 wherein said counter electrode comprises a graphite plate, gas carbon plate, or graphite fabric, or a platinum plate.

65. The apparatus of claim 64 further comprising means for admitting a pre-defined volume of said organic electrolyte solution into said container.

66. The apparatus of claim 65 wherein said means for admitting said pre-defined volume of said organic electrolyte solution comprises an opening in said counter electrode, through which said pre-defined volume is passed into said container.

67. The apparatus of claim 66 wherein said means for admitting said pre-defined volume of said organic electrolyte solution comprise a pump operably configured to pump said predefined volume of said organic electrolyte solution from a reservoir and through said opening.

68. The apparatus of claim 56 further comprising a drain operably configured to drain the organic electrolyte after said oxide layer is formed to a desired thickness on the flat conductive surface of the working electrode.

69. The apparatus of claim 56 wherein said chemicals comprise a source of oxygen sufficient to permit said oxide layer to be formed to a desired thickness.

70. The apparatus of claim 69 wherein said source of oxygen comprises dissolved oxygen or at least one oxygen precursor.

71. The apparatus of claim 70 wherein said source of oxygen comprises at least one oxygen precursor and wherein the at least one oxygen precursor comprises at least one of dissolved nitrate, nitrite, hydrogen peroxide and traces of water.

72. The apparatus of claim 56 wherein said direct current source is operably configured to cause said electric current to flow in a direction in which the working electrode acts as an anode.

73. The apparatus of claim 56 further comprising means for agitating said electrolyte while said electric current is flowing.

74. The apparatus of claim 73 wherein said means for agitating comprises means for causing flow of said volume of organic electrolyte solution to pass through the space defined between said flat conductive surface of the working electrode and said flat conductive surface of said counter electrode.

75. The apparatus of claim 72 wherein said organic electrolyte solution is protic and said chemicals include at least one of methanol, ethanol, isopropanol, ethylene glycol, and tetrahydrofurfuryl alcohol.

76. The apparatus of claim 72 wherein said organic electrolyte solution is aprotic and said chemicals include at least one of N-methylacetamide and acetonitrile.

77. The apparatus of claim 72 further comprising means for maintaining said organic electrolyte solution, the working electrode and said counter electrode at a constant temperature of between about 15 degrees Celsius to about 90 degrees Celsius.

78. The apparatus of claim 72 wherein said direct current source comprises means for maintaining said electric current at a level at least sufficient to maintain oxide formation as oxide formation occurs and presents resistance to said electric current.

79. The apparatus of claim 72 further comprising means for terminating said flow of electric current when said flow of electric current meets a criterion.

80. The apparatus of claim 79 wherein said criterion includes a condition that said oxide layer has a pre-defined thickness,

81. The apparatus of claim 72 wherein said direct current source comprises means for maintaining said electric current at a level to cause a current density of between about 1 mA/cm² to about 100 mA/cm² in said volume of organic electrolyte solution.

82. The apparatus of claim 56 wherein the oxide layer is a metal oxide layer, wherein said electrolyte solution includes at least one ionic source of metal and wherein said direct current source is operably configured to cause said electric current to flow in a direction in which the working electrode acts as a cathode.

83. The apparatus of claim 82 wherein said pre-defined volume of said electrolyte solution is sufficient to ensure said flat conductive surface of said counter electrode and said flat conductive surface of said working electrode will be in contact with said electrolyte solution and wherein said pre-defined volume has a concentration of metal ions sufficient to plate said metal oxide onto said flat conductive surface of said working electrode to a desired thickness of said metal oxide layer.

84. The apparatus of claim 82 wherein said metal oxide layer comprises aluminum oxide and wherein said ionic source of metal comprises at least one dissolved aluminum salt or at least one aluminate or a combination of said at least one dissolved aluminum salt or at least one aluminate.

85. The apparatus of claim 82 wherein said metal oxide layer comprises indium oxide and wherein said ionic source of metal comprises at least one dissolved indium salt.

86. The apparatus of claim 82 wherein said metal oxide layer comprises zinc oxide and wherein said ionic source of metal comprises at least one dissolved zinc salt or at least one zincate or a combination of said at least one dissolved zinc salt or at least one zincate.

87. The apparatus of claim 82 wherein said metal oxide layer comprises aluminum-doped zinc oxide and wherein said ionic source of metal comprises at least one dissolved zinc salt and at least one dissolved aluminum salt.

88. The apparatus of claim 82 wherein said metal oxide layer comprises indium-doped zinc oxide and wherein said ionic source of metal comprises at least one dissolved zinc salt and at least one dissolved indium salt.

89. The apparatus of claim 82 wherein said metal oxide layer comprises chlorine-doped zinc oxide and wherein said ionic source of metal comprises at least one dissolved zinc salt and wherein said organic electrolyte solution comprises at least one dissolved chloride.

90. The apparatus of claim 82 wherein said metal oxide layer comprises tin-doped indium oxide and wherein said ionic source of metal comprises at least one dissolved indium salt and at least one dissolved tin salt.

91. The apparatus of claim 82 wherein said organic electrolyte solution is maintained still while said electric current is flowing.

92. The apparatus of claim 82 wherein said organic electrolyte solution is protic and wherein said chemicals include at least one of methanol, ethanol, propanol, isopropanol, ethylene glycol, and glycerol.

93. The apparatus of claim 82 wherein said organic electrolyte solution is aprotic and wherein said chemicals include at least one of dimethylsulfoxide (DMSO) and propylene carbonate.

94. The apparatus of claim 82 further comprising means for maintaining said organic electrolyte solution, the working electrode and said counter electrode at a temperature between about 15 degrees Celsius to about 90 degrees Celsius.

95. The apparatus of claim 82 further comprising means for terminating said flow of electric current when a pre-defined number of coulombs has passed through said organic electrolyte solution.

96. The apparatus of claim 95 wherein said pre-defined number of coulombs is sufficient to cause substantially all of said ionic source of metal in said organic electrolyte solution to be depleted from said organic electrolyte solution and oxidized on said flat conductive surface of said working electrode to facilitate producing said oxide layer to a desired thickness.

97. The apparatus of claim 96 wherein said means for maintaining said electric current at a level comprises means for maintaining said electric current at a level that produces a current density of between about 0.1 mA/cm² to about 100 mA/cm² in said organic electrolyte solution.

98. The apparatus of claim 82 wherein said means for maintaining said electric current comprises means for maintaining said electric current at a level that produces an electric current concentration in said organic electrolyte solution between about 100 mA/cm³ to about 1000 mA/cm³.

99. The apparatus of claim 82 further comprising means for draining the organic electrolyte solution substantially depleted of said metal ions after said flat conductive surface of said cathode has been plated by said metal oxide to said desired thickness.

100. An apparatus for forming an oxide layer on a semiconductor wafer, the apparatus comprising the apparatus of claim 56 wherein the working electrode comprises said semiconductor wafer, said flat conductive surface is on a front side or a back side of said semiconductor wafer and said oxide layer is a semiconductor oxide layer.

101. The apparatus of claim 100 wherein said semiconductor wafer includes an n-type crystalline semiconductor wafer or a p-type crystalline semiconductor wafer.

102. The apparatus of claim 101 wherein said flat conductive surface is on an n-type portion or a p-type portion of said crystalline semiconductor wafer or wherein said flat conductive surface is on a metal oxide layer on an n-type portion or a p-type portion of said crystalline semiconductor wafer.

103. The apparatus of claim 101 wherein the apparatus further includes means for exposing said flat conductive surface of the working electrode to light for at least a portion of a time during which said electric current is flowing.

104. The apparatus of claim 103 wherein said means for exposing said flat conductive surface of the working electrode to light comprises means for admitting light into said space between said flat conductive surface of the working electrode and said flat conductive surface of said counter electrode.

105. The apparatus of claim 104 wherein said means for admitting light into said space comprises light transmissive portions in said counter electrode to permit light to pass through said light transmissive portions and impinge upon said flat conductive surface of said working electrode.

106. The apparatus of claim 104 wherein said means for admitting light comprises a light-transmissive portion formed in said container for admitting light into said space through at least a portion of at least one peripheral edge of said space.

107. An apparatus for forming a metal oxide layer on a semiconductor wafer, the apparatus comprising the apparatus of claim 82 wherein the working electrode comprises said semiconductor wafer, said flat conductive surface of the working electrode is on a front side or a back side of said semiconductor wafer or wherein said flat conductive surface of the working electrode is on a semiconductor oxide layer on a front side or rear side of said semiconductor wafer.

108. The apparatus of claim 107 wherein said flat conductive surface of said working electrode semiconductor wafer includes an n-type portion or a p-type portion of a crystalline silicon photovoltaic cell.

109. The apparatus of claim 107 wherein the apparatus further includes means for exposing the flat conductive surface of the working electrode to light for at least a portion of a time during which said electric current is flowing.

110. The apparatus of claim 109 wherein said means for exposing said flat conductive surface of the working electrode to light comprises means for admitting light into said space between said flat conductive surface of the working electrode and said flat conductive surface of said counter electrode.

111. The apparatus of claim 109 wherein said means for admitting light into said space comprises light transmissive portions in said counter electrode to permit light to pass through said light transmissive portions and impinge upon said flat conductive surface of said working electrode.

112. The apparatus of claim 109 wherein said means for admitting light comprises a light-transmissive portion formed in said container for admitting light into said space through at least a portion of at least one peripheral edge of said space.
